(19) United States
(12) Patent Application Publication
(10) Pub. No.: US 2025/0239434 A1
(43) Pub. Date: Jul. 24, 2025

(54) PLASMA SYSTEMS AND METHODS FOR USING SQUARE-SHAPED PULSE SIGNALS

(71) Applicant: Lam Research Corporation, Fremont, CA (US)

(72) Inventors: Alexei M. Marakhtanov, Albany, CA (US); Fabio Righetti, Redwood City, CA (US); Lin Zhao, Fremont, CA (US); Kenneth Lucchesi, Newark, CA (US); Rajesh Dorai, Pleasanton, CA (US); John P. Holland, San Jose, CA (US); Alexander Declan Bennet, Sunnyvale, CA (US); Roger Patrick, Mountain View, CA (US)

(21) Appl. No.: 18/290,738

(22) PCT Filed: Jul. 18, 2022
(86) PCT No.: PCT/US2022/037516

§ 371 Date: Jan. 19, 2024

Related U.S. Application Data
(60) Provisional application No. 63/225,120, filed on Jul. 23, 2021.

(51) Int. Cl. H01J 37/32; H01L 21/67

(52) U.S. Cl. CPC H01J 37/32146; H01J 37/32642; H01J 37/32091; H01J 2237/334; H01L 21/67253

(57) ABSTRACT

A system for using a square wave signal for processing a substrate is described. The system includes a first pulse generator that generates a first square wave signal of a first frequency. The system further includes a first filter that filters a second frequency from interfering with the first square wave signal to provide a first filter output signal. The first filter provides the first filter output signal via a first transmission line to an electrode of a plasma chamber. The system includes a second pulse generator that generates a second square wave signal of a third frequency. The system also includes a second filter that filters the second frequency from interfering with the second square wave signal to provide a second filter output signal. The second filter provides the second filter output signal via a second transmission line to an edge ring of the plasma chamber.

### FIELD

The present embodiments relate to systems and methods for using square-shaped pulse signals.

### BACKGROUND

In general, a parallel-plate plasma etching apparatus of a capacitive coupling type includes a chamber with a pair of parallel-plate electrodes, such as upper and lower electrodes, disposed therein. While a process gas is supplied into the chamber, a radio frequency (RF) signal is applied to at least one of the electrodes to form an electric field between the electrodes. A process gas is turned into plasma by the RF signal, thereby performing plasma etching on a predetermined layer disposed on a semiconductor wafer. However, an etch rate for etching the predetermined layer may not be achieved.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for using square-shaped pulse signals. It should be appreciated that the present embodiments can be implemented in numerous ways, e.g., a process, an apparatus, a system, a device, or a method on a computer readable medium. Several embodiments are described below.

In one embodiment, a system for using square-shaped pulse signals for processing a substrate is described. The system includes a first pulse generator that generates a first square wave signal of a first frequency. The system further includes a first filter that receives the first square wave signal and filters a second frequency from interfering with the first square wave signal to provide a first filter output signal. The first filter provides the first filter output signal to an electrode disposed within a plasma chamber via a first radio frequency (RF) transmission line. The system includes a second pulse generator that generates a second square wave signal of a third frequency. The system also includes a second filter that receives the second square wave signal and filters the second frequency from interfering with the second square wave signal to provide a second filter output signal. The second filter provides the second filter output signal via a second RF transmission line to an edge ring disposed within the plasma chamber.

In one embodiment, a system for using a square-shaped pulse signal for processing a substrate is described. The system includes a first pulse generator that generates a first square wave signal of a first frequency. The system further includes a first filter that receives the first square wave signal and filters a second frequency from interfering with the first square wave signal to provide a first filter output signal. The system includes an RF generator that generates an RF signal. The system also includes an impedance matching circuit that receives the RF signal and output a modified signal based on the RF signal. The system includes an RF transmission line coupled to the first filter and the impedance matching circuit to receive the first filter output signal and the modified signal. The RF transmission line combines the first filter output signal and the modified signal to output a combined signal. The combined signal is provided to a lower electrode disposed within a plasma chamber.

In an embodiment, a method for using square-shaped pulse signals for processing a substrate is described. The method includes generating a first square wave signal of a first frequency and filtering a second frequency from interfering with the first square wave signal to output a first filter output signal. The method further includes generating a second square wave signal of a third frequency and filtering the second frequency from interfering with the second square wave signal to output a second filter output signal. The method includes providing the first filter output signal to an electrode of a plasma chamber and providing the second filter output signal to an edge ring of the plasma chamber.

Several advantages of the herein described systems and methods for using square-shaped pulse signals include increasing a processing rate of a semiconductor substrate, such as a wafer. Instead of RF signals, the square-shaped pulse signals are used to etch the semiconductor substrate. By using the square-shaped pulse signals, there is an increase in a number of ions that having high amounts of ion energies compared to a number of ions generated using the RF signals. As such, the processing rate increases.

Additional advantages of the herein described systems and methods for using square-shaped pulse signals include achieving uniformity across a top surface of the semiconductor substrate. A first square wave signal is supplied to an electrode of a plasma chamber and a second square wave signal is supplied to an edge ring of the plasma chamber. One or more parameter characteristics, such as a frequency, a phase, and a magnitude, of a parameter of the second square wave signal are adjusted until the parameter is within a predetermined range from a parameter of the first square wave signal to achieve the uniformity. Further advantages of the herein described systems and methods for using square-shaped pulse signals include adjusting the parameter of the first square wave signal and the parameter of the second square wave signal to achieve a predetermined processing rate.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system for generating square waves.

FIG. 2A is a diagram of an embodiment of another system to illustrate generation of square waves for processing a substrate.

FIG. 2B is a diagram of an embodiment of a system, which is similar to the system of FIG. 2A, except that in the system of FIG. 2B, a high frequency (HF) filter is located within a filter housing and an HF radio frequency (RF) match is located within a match housing.

FIG. 3A is an embodiment of a graph to illustrate a square wave signal that is generated by an LF RF pulse generator.

FIG. 3B is an embodiment of a graph to illustrate another square wave signal that is generated by another LF RF pulse generator.

FIG. 3C is a diagram of an embodiment of a graph to illustrate an RF signal that is generated by an HF RF generator.

FIG. 3D is an embodiment of a graph to illustrate a clock signal.

FIG. 4A is an embodiment of an inductor to illustrate an HF filter.

FIG. 4B is an embodiment of a parallel circuit to illustrate an HF filter.

FIG. 5 is a flowchart to illustrate an embodiment of a method for achieving uniformity across a surface of the substrate.

FIG. 6A is a diagram of an embodiment of a graph to illustrate a plot of a voltage of an RF signal that is generated by a 400 kilohertz (kHz) RF generator versus time.

FIG. 6B is a diagram of an embodiment of a graph to illustrate a plot of an envelope of a number of ions of plasma that is generated when the 400 kHz RF generator, illustrated with reference to FIG. 6A, is used.

FIG. 7A is a diagram of an embodiment of a graph to illustrate a plot of a voltage of a square wave signal that is output as a parameter signal from a sensor.

FIG. 7B is a diagram of an embodiment of a graph to illustrate a plot of an envelope of a number of ions of plasma that is generated when an LF RF pulse generator that generates the square wave signal, illustrated with reference to FIG. 7A, is used.

FIG. 8 is a diagram of an embodiment of an LF RF pulse generator.

FIG. 9A is a diagram of an embodiment of a graph to illustrate contact etch rates for square wave signals and sinusoidal RF signals.

FIG. 9B is a diagram of an embodiment of a graph to illustrate contact critical dimension (CD) growth rates for square wave signals and sinusoidal RF signals.

### DETAILED DESCRIPTION

The following embodiments describe systems and methods for using square-shaped pulse signals. It will be apparent that the present embodiments may be practiced without some or all of these specific details. In other instances, well known operations have not been described in detail in order not to unnecessarily obscure the present embodiments.

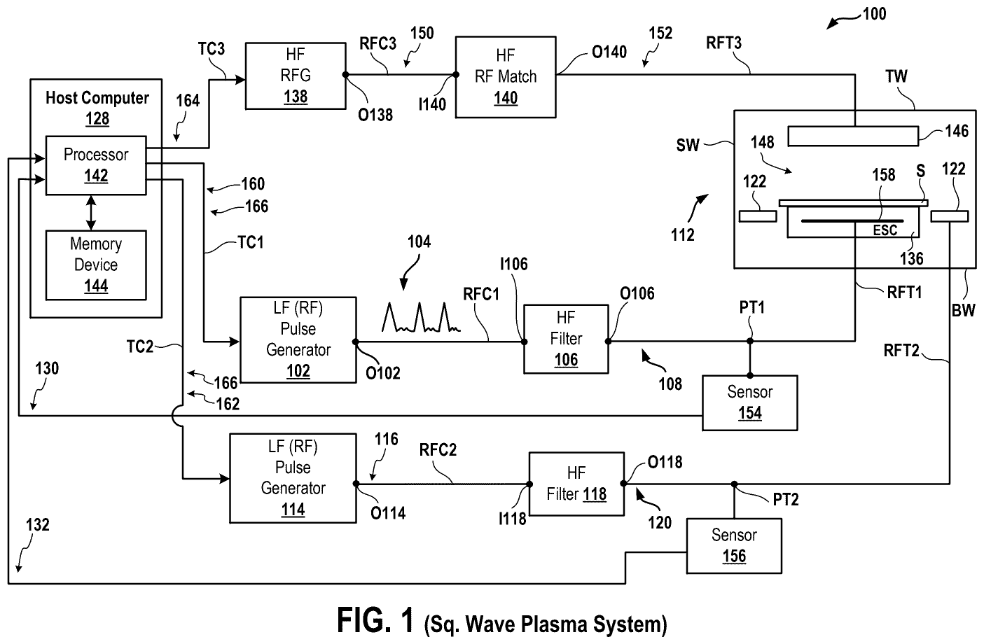

FIG. 1 is a diagram of an embodiment of a system 100 for generating square waves. The system 100 includes a low frequency (LF) radio frequency (RF) pulse generator 102, another LF RF pulse generator 114, a high frequency (HF) filter 106, another HF filter 118, a plasma chamber 112, a host computer 128, an HF RF generator (RFG) 138, and an HF RF match 140.

An example of a pulse generator is a square-shaped pulse generator that generates a high-voltage nanosecond pulse periodically. In one embodiment, the pulse generator is a nanosecond pulser. An example of the nanosecond pulser is described in U.S. Patent Application Publication No. 2015/0130525.

Examples of low frequency include frequencies ranging from and including 10 kilohertz (kHz) to 800 kHz. To illustrate, the low frequency is a baseline frequency of 400 kHz. To further illustrate, the frequency of operation of the LF RF pulse generator 102 or 114 is 400 kHz. As another illustration, a frequency of operation of the LF RF pulse generator 102 is the same as the frequency of operation of the LF RF pulse generator 114. To further illustrate, both the LF RF pulse generators 102 and 114 operate at a baseline frequency of 400 kHz. As yet another illustration, a frequency of operation of the LF RF pulse generator 102 is different from the frequency of operation of the LF RF pulse generator 114. To further illustrate, the LF RF pulse generator 102 operates at a baseline frequency of 100 kHz and the LF RF pulse generator 114 operates at a baseline frequency of 400 kHz.

Examples of high frequency include frequencies ranging from and including 13 megahertz (MHz) to 120 MHz. For example, the high frequency is a baseline frequency of 13.56 MHz or 27 MHz or 40 MHz or 60 MHz or 100 MHz. To illustrate, a frequency of operation of the HF RF generator 138 is 60 MHz. The high frequency is greater than the low frequency. For example, the low frequency is 400 kHz and the high frequency is 60 MHz. As another example, the low frequency is 100 kHz and the high frequency is 60 MHz.

Examples of the host computer 128 include a desktop computer, a laptop computer, a tablet, a smart phone, and a controller. The host computer 128 includes a processor 142 and a memory device 144. As an example, the processor 142 can be an application specific integrated circuit (ASIC), a central processing unit (CPU), a field programmable gate array (FPGA), a programmable logic device (PLD), an integrated controller, or a microcontroller. Examples of the memory device 144 include a read-only memory (ROM) and a random access memory (RAM). To illustrate, the memory device 144 is a flash memory or a redundant array of independent discs (RAID). The processor 142 is coupled to the memory device 144.

Examples of a match include an impedance matching circuit or an impedance matching network. For example, the match is a series of circuit components, such as capacitors, inductors, and resistors. The circuit components are coupled to each other. To illustrate, two of the circuit components are coupled to each other in a series or in parallel.

The plasma chamber 112 includes a substrate support 136, such as an electrostatic chuck (ESC). The plasma chamber 112 further includes an upper electrode 146 that is located above the substrate support 136 to form a gap 148 between the upper electrode 146 and the substrate support 136. The upper electrode 146 faces the substrate support 136. A lower electrode 158, embedded within the substrate support 136, is made from a metal, such as aluminum or an alloy of aluminum. The substrate support 136 is made from the metal and from a ceramic, such as aluminum oxide (Al₂O₃). The upper electrode 146 is fabricated from the metal.

The plasma chamber 112 also includes an edge ring 122, such as a tunable edge sheath (TES) ring, which surrounds the substrate support 136. As an example, the edge ring 122 is fabricated from a conductive material, such as silicon, boron doped single crystalline silicon, silicon carbide, an alloy of silicon, or a combination thereof. It should be noted that the edge ring 122 has an annular body, such as a circular body, or ring-shaped body, or dish-shaped body. To illustrate, the edge ring 122 has an inner radius and an outer radius, and the inner radius is greater than a radius of the substrate support 136. An example of the plasma chamber 112 is a capacitively coupled plasma (CCP) chamber.

The system 100 further includes a sensor 154, which is coupled to a point PT1, on an RF rod of an RF transmission line RFT1. Examples of the sensor 154 include a voltage sensor and a power sensor. Also, the system 100 includes a sensor 156, which is coupled to a point PT2, on an RF rod of an RF transmission line RFT2. Examples of the sensor 156 include a voltage sensor and a power sensor.

The sensors 154 and 156 are coupled to the processor 142. For example, the sensor 154 is coupled via a first transfer cable to the processor 142 and the sensor 156 is coupled via a second transfer cable to the processor 142.

The processor 142 is coupled to the LF RF pulse generator 102 via a transfer cable TC1. Also, the processor 128 is coupled to the LF RF pulse generator 114 via another transfer cable TC2. The processor 142 is coupled to the HF RF generator 138 via a transfer cable TC3. Examples of a transfer cable include a cable that allows for serial transfer of data, or a cable that allows for a parallel transfer of data, or a cable that allows for transfer of data using a Universal Serial Bus (USB) protocol.

An output O102 of the LF RF pulse generator 102 is coupled to an input I106 of the HF filter 106 via an RF cable RFC1 and an output O106 of the HF filter 106 is coupled to the lower electrode 158 via the RF transmission line RFT1. For example, there is no impedance matching circuit between the LF RF pulse generator 102 and the lower electrode 158. To illustrate, an impedance matching circuit includes a network of circuit components, such as capacitors and inductors. To further illustrate, the impedance matching circuit includes multiple shunt circuits and multiple series circuits. The impedance matching circuit matches an impedance of a load coupled to an output of the impedance matching circuit with an impedance of a source coupled to an input of the impedance matching circuit. The impedances are matched to modify an impedance of a signal that is received by the impedance matching circuit to output a modified signal.

Similarly, an output O114 of the LF RF pulse generator 114 is coupled to an input I118 of the HF filter 118 via an RF cable RFC2 and an output O118 of the HF filter 118 is coupled to the edge ring 122 via the RF transmission line RFT2. For example, there is no impedance matching circuit between the LF RF pulse generator 114 and the edge ring 122. Also an output O138 of the HF RF generator 138 is coupled to an input I140 of the HF RF match 140 via an RF cable RFC3 and an output O140 of the HF RF match 140 is coupled to the upper electrode 146 via an RF transmission line RFT3.

An example of an RF cable includes a coaxial cable having a center conductor that is surrounded by an RF cover. As an example, each RF cable RFC1 and RFC2 is capable of transferring a square wave signal having voltage that ranges from 100 volts to 20 kilovolts (kV). An example of an RF transmission line includes an RF rod that is surrounded by an RF tunnel, with an insulator between the RF rod and the RF tunnel. An RF tunnel is sometimes referred to herein as an RF ground. The RF rod, the RF ground, and the insulator are components of the RF transmission line. Another example of an RF transmission line includes a combination of one or more RF straps, an RF rod, and an RF ground. In the example, the one or more RF straps are coupled to the RF rod. Also, in the example, the RF rod is surrounded by the RF ground.

The processor 142 generates an instruction signal 160 having a parameter, and sends the instruction signal 160 to the LF RF pulse generator 102 via the transfer cable TC1. Examples of a parameter, as used herein, include voltage and power. The parameter has characteristics, such as, a magnitude, a frequency, and a phase. Examples of the magnitude of the parameter include a peak-to-peak magnitude and a zero-to-peak magnitude. Upon receiving the parameter from the processor 142, the LF RF pulse generator 102 stores the parameter within one or more memory devices of the LF RF pulse generator 102.

The processor 142 further sends a synchronization signal 166 via the transfer cable TC1 to the LF RF pulse generator 102 and also sends the synchronization signal 166 via the transfer cable TC2 to the LF RF pulse generator 114. An example of the synchronization signal 166 is a signal having a single digital pulse or a trigger pulse.

Upon receiving the synchronization signal 166, the LF RF pulse generator 102 generates a square wave signal 104 based on the parameter, and supplies the square wave signal 104 at the output O102. The square wave signal 104 increases directionality of ions and a number of ions of plasma towards a center region of the substrate S compared to a non-square wave signal. With the increase in the directionality and the number of ions, the center region is processed at a high rate. For example, the center region is etched at the high rate or materials are deposited on the center region at the high rate or the center region is cleaned at the high rate.

The square wave signal 104 is transferred via the RF cable RFC1 to the input I106. The HF filter 106 filters out, such as reduces or removes, the high frequency to reduce chances or prevent the high frequency from interfering with the low frequency of the square wave signal 104 to output a signal 108 at the output O106. As such, the HF RF filter 106 protects the LF RF pulse generator 102 from being negatively impacted or damaged by the high frequency. As an example, the high frequency is received by the HF filter 106 from the upper electrode 146 via the gap 148, the electrode 158, and the RF transmission line RFT1. An example of the filter output signal 108 is a square wave signal. To illustrate, the filter output signal 108 has the same or similar shape as that of the square wave signal 104. The filter output signal 108 is transferred via the RF transmission line RFT1 to the lower electrode 158.

In a similar manner, the processor 142 generates an instruction signal 162 having a parameter, and sends the instruction signal 162 to the LF RF pulse generator 114 via the transfer cable TC2. Upon receiving the parameter from the processor 142, the LF RF pulse generator 114 stores the parameter and within one or more memory devices of the LF RF generator 114.

Upon receiving the synchronization signal 166, the LF RF pulse generator 114 generates a square wave signal 116 based on the parameter, and supplies the square wave signal 116 at the output O114. The square wave signal 116 increases directionality of ions and a number of ions of plasma towards an edge region of the substrate S compared to a non-square wave signal. With the increase in the directionality and the number of ions, the edge region is etched at a higher etch rate. It should be noted that the center region of the substrate S is exclusive of the edge region and vice versa. For example, the edge region is a fraction of the center region. As another example, the edge region is located peripheral to or at a periphery of the center region.

As an example, a square wave signal, as described herein, includes main pulses and each main pulse has a width that ranges from 10 nanoseconds (ns) to 500 ns and a rise time of about 50 ns. To illustrate, each main pulse of the square wave signal has a rise time that ranges from 40 ns to 60 ns.

The square wave signal 116 is transferred via the RF cable RFC2 to the input I118. The HF filter 118 filters out, such as reduces or removes, the high frequency to reduce chances or prevent the high frequency from interfering with the low frequency of the square wave signal 116 to output a signal 120 at the output O118. As an example, the high frequency is received by the HF filter 118 from the upper electrode 146 via the gap 148, the edge ring 122, and the RF transmission line RFT2. The filter output signal 120 is transferred via the RF transmission line RFT2 to the edge ring 122. An example of the filter output signal 120 is a square wave signal. To illustrate, the filter output signal 120 has the same or similar shape as that of the square wave signal 116.

Furthermore, the processor 142 generates an instruction signal 164 including a parameter, and sends the instruction signal 164 to the HF RF generator 138 via the transfer cable TC3. Upon receiving the parameter, the HF RF generator 138 stores the parameter within one or more memory devices of the HF RF generator 138. Also, the processor 142 sends the synchronization signal 166 via the transfer cable TC3 to the HF RF generator 138.

Upon receiving the synchronization signal 166, the HF RF generator 138 generates an RF signal 150 based on the parameter, and supplies the RF signal 150 at the output O138. The RF signal 150 is transferred via the RF cable RFC3 to the input I140. The HF RF match 140 matches an impedance of a load coupled to the output O140 with an impedance of a source coupled to the input I140 to modify an impedance of the RF signal 150. An example of the source coupled to the input I140 includes the RF cable RFC3 and the HF RF generator 138. An example of the load coupled to the output O140 includes the RF transmission line RFT3 and the plasma chamber 112. The impedance of the RF signal 150 is modified to output a modified RF signal 152 at the output O140. The modified RF signal 152 is transferred via the RF transmission line RFT3 to the upper electrode 146.

When one or more process gases are supplied to the gap 148 in addition to the filter output signals 108 and 120 and the modified RF signal 152, plasma is stricken or maintained within the gap 148 to process the substrate S. Examples of processing the substrate S include etching the substrate S, or depositing one or more material layers on the substrate S, or cleaning the substrate S, or sputtering the substrate S. Examples of the one or more process gases include an oxygen containing gas, a fluorine containing gas, and a combination thereof. Examples of the substrate S include a semiconductor wafer and a substrate stack. To illustrate, the substrate stack includes one or more layers, such as a metal layer and an oxide layer. The substrate stack further includes a substrate layer on which the one or more layers are fabricated to form one or more integrated circuits on the substrate layer.

While the substrate S is being processed, the sensor 154 measures a parameter of the filter output signal 108 at the point PT1 to generate a parameter signal 130. For example, a parameter of the parameter signal 130 is the same as a parameter of the filter output signal 108. To illustrate, a frequency of the parameter signal 130 is the same as a frequency of the filter output signal 108, a phase of the parameter signal 130 is the same as a phase of the filter output signal 108, and a magnitude of the parameter signal 130 is the same a magnitude of the filter output signal 108.

The parameter signal 130 is sent from the sensor 154 to the processor 142. The processor 142 determines whether a parameter of the parameter signal 130 is within a predetermined range from a predetermined parameter. For example, the processor 142 applies a Fourier transform to the parameter signal 130 to determine a band of frequencies. The processor 142 further calculates a statistical value, such as a moving average or a moving median, from the frequencies of the band to determine a frequency of the parameter signal 130. In the example, the processor 142 determines whether the frequency of the parameter signal 130 is within a predetermined frequency range from a predetermined frequency. Further, in the example, the processor 142 determines whether a phase of the parameter signal 130 is within a predetermined phase range from a predetermined phase. In the example, the processor 142 determines the phase of the parameter signal 130 by determining a time at which a magnitude of the parameter signal 130 is at a predetermined parameter value. Also, in the example, the processor 114 determines a magnitude of the parameter signal 130, and determines whether the magnitude is within a predetermined magnitude range from a predetermined magnitude.

Upon determining that the parameter of the parameter signal 130 is within the predetermined range from the predetermined parameter, the processor 142 determines not to modify a parameter of the square wave signal 104 that is generated by the LF RF pulse generator 102. For example, in response to determining that the frequency of the parameter signal 130 is within the predetermined frequency range from the predetermined frequency, the phase of the parameter signal 130 is within the predetermined phase range from the predetermined phase, and the magnitude of the parameter signal 130 is within the predetermined magnitude range from the predetermined magnitude, the processor 142 determines not to change the parameter of the square wave signal 104. To illustrate, the processor 142 does not generate an additional instruction signal different from the instruction signal 160. For example, the processor 142 does not generate the additional instruction signal that includes a different parameter than that included within the instruction signal 160. As such, the LF RF pulse generator 102 continues to generate and send the square wave signal 104.

On the other hand, in response to determining that the parameter of the parameter signal 130 is not within the predetermined range from the predetermined parameter, the processor 142 determines to modify the parameter of the square wave signal 104. For example, in response to determining that the frequency of the parameter signal 130 is not within the predetermined frequency range from the predetermined frequency, or the phase of the parameter signal 130 is not within the predetermined phase range from the predetermined phase, or the magnitude of the parameter signal 130 is not within the predetermined magnitude range from the predetermined magnitude, the processor 142 determines to change the parameter of the square wave signal 104.

To illustrate, the processor 142 generates the additional instruction signal that includes the different parameter than that included within the instruction signal 160. To further illustrate, in response to determining that the frequency of the parameter signal 130 is not within the predetermined frequency range from the predetermined frequency, the processor 114 determines to change the frequency of the square wave signal 104. Also, in the further illustration, upon determining that the phase of the parameter signal 130 is not within the predetermined phase range from the predetermined phase, the processor 114 determines to change the phase of the square wave signal 104. Moreover, in the further illustration, in response to determining that the magnitude of the parameter signal 130 is not within the predetermined magnitude range from the predetermined magnitude, the processor 142 determines to change the magnitude of the square wave signal 104.

Upon receiving the additional instruction signal from the processor 142 regarding changing the square wave signal 104, the LF RF pulse generator 102 generates an additional square wave signal based on the different parameter. In this manner, the processor 142 continues to control the LF RF pulse generator 102 until a parameter of a parameter signal received from the sensor 154 is within the predetermined range from the predetermined parameter. When the parameter signal received from the sensor 154 is within the predetermined range from the predetermined parameter, a predetermined rate of processing the center region of the substrate S is achieved. For example, the center region of the substrate S is etched or materials are deposited on the substrate S at the predetermined rate.

In addition, while the substrate S is being processed, the sensor 156 measures a parameter of the filter output signal 120 at the point PT2 to generate a parameter signal 132. As an example, a parameter of the parameter signal 132 is the same as the parameter of the filter output signal 120. To illustrate, a frequency of the parameter signal 132 is the same as a frequency of the filter output signal 120, a phase of the parameter signal 132 is the same as a phase of the filter output signal 120, and a magnitude of the parameter signal 132 is the same as a magnitude of the filter output signal 120.

The parameter signal 132 is sent from the sensor 156 to the processor 142. The processor 142 determines whether a parameter of the parameter signal 132 is within a predetermined range from a predetermined parameter. For example, the processor 142 applies a Fourier transform to the parameter signal 132 to determine a band of frequencies. In the example, the processor 142 further calculates a statistical value, such as a moving average or a moving median, from the frequencies of the band to determine a frequency of the parameter signal 132. Also, in the example, the processor 142 determines whether the frequency of the parameter signal 132 is within a predetermined frequency range from a predetermined frequency. Further, in the example, the processor 142 determines whether a phase of the parameter signal 132 is within a predetermined phase range from a predetermined phase. In the example, the processor 142 determines the phase of the parameter signal 132 by determining a time at which a magnitude of the parameter signal 132 is at a predetermined parameter value. Also, in the example, the processor 142 determines a magnitude of the parameter signal 132, and determines whether the magnitude is within a predetermined magnitude range from a predetermined magnitude.

Upon determining that the parameter of the parameter signal 132 is within the predetermined range from the predetermined parameter, the processor 142 determines not to modify a parameter of the square wave signal 116 that is generated by the LF RF pulse generator 114. For example, in response to determining that the frequency of the parameter signal 132 is within the predetermined frequency range from the predetermined frequency, the phase of the parameter signal 132 is within the predetermined phase range from the predetermined phase, and the magnitude of the parameter signal 132 is within the predetermined magnitude range from the predetermined magnitude, the processor 142 determines not to change the parameter of the parameter signal 132. To illustrate, the processor 142 does not generate a further instruction signal different from the instruction signal 162. For example, the processor 142 does not generate the further instruction signal that includes a different parameter than that included within the instruction signal 162. As such, the LF RF pulse generator 114 continues to generate and send the square wave signal 116.

On the other hand, in response to determining that the parameter of the parameter signal 132 is not within the predetermined range from the predetermined parameter, the processor 142 determines to modify the parameter of the square wave signal 116 that is generated by the LF RF pulse generator 114. For example, in response to determining that the frequency of the parameter signal 132 is not within the predetermined frequency range from the predetermined frequency, or the phase of the parameter signal 132 is not within the predetermined phase range from the predetermined phase, or the magnitude of the parameter signal 132 is not within the predetermined magnitude range from the predetermined magnitude, the processor 142 determines to change the parameter of the square wave signal 116.

To illustrate, the processor 142 generates the further instruction signal that includes the different parameter than that included within the instruction signal 162. To further illustrate, in response to determining that the frequency of the parameter signal 132 is not within the predetermined frequency range from the predetermined frequency, the processor 142 determines to change the frequency of the square wave signal 116. Also, in the further illustration, upon determining that the phase of the parameter signal 132 is not within the predetermined phase range from the predetermined phase, the processor 142 determines to change the phase of the square wave signal 116. Moreover, in the further illustration, in response to determining that the magnitude of the parameter signal 132 is not within the predetermined magnitude range from the predetermined magnitude, the processor 142 determines to change the magnitude of the square wave signal 116.

Upon receiving the further instruction from the processor 142 regarding changing the square wave signal 116, the LF RF pulse generator 114 generates an additional square wave signal based on the different parameter. In this manner, the processor 142 continues to control the LF RF pulse generator 114 until a parameter of a parameter signal received from the sensor 156 is within the predetermined range from the predetermined parameter. When the parameter signal received from the sensor 156 is within the predetermined range from the predetermined parameter, the predetermined rate of processing the substrate S is achieved.

In an embodiment, the sensor 154 is coupled to any point, on the RF transmission line RFT1, between the output O106 and the lower electrode 158. For example, the sensor 154 is coupled to the output O106 or to an internal point on the RF rod of the RF transmission line RFT1. The internal point is located within an enclosure, such as a housing, of the plasma chamber 112. As an example, the housing of the plasma chamber 112 includes a top wall TW of the plasma chamber 112, a bottom wall BW of the plasma chamber 112, and a side wall SW of the plasma chamber 112. The side wall SW is attached to the top wall TW at one end of the side wall SW and to the bottom wall BW at an opposite end of the side wall SW.

Similarly, in one embodiment, the sensor 156 is coupled to any point, on the RF transmission line RFT2, between the output O118 and the edge electrode 122. For example, the sensor 156 is coupled to the output O118 or to an internal point on the RF rod of the RF transmission line RFT2. The internal point is located within the enclosure of the plasma chamber 112.

In an embodiment, the terms match, impedance matching circuit, and impedance matching network are used herein interchangeably.

In one embodiment, the upper electrode 146 is coupled to a reference potential, such as a ground voltage or a negative voltage, instead of being coupled to the RF transmission line RFT3.

In an embodiment, a square-wave signal is sometimes referred to herein as a square-shaped pulse signal or a square waveform or a square RF waveform. For example, between two consecutive main pulses of the square-wave signal, a square shape or a substantially square shape is formed.

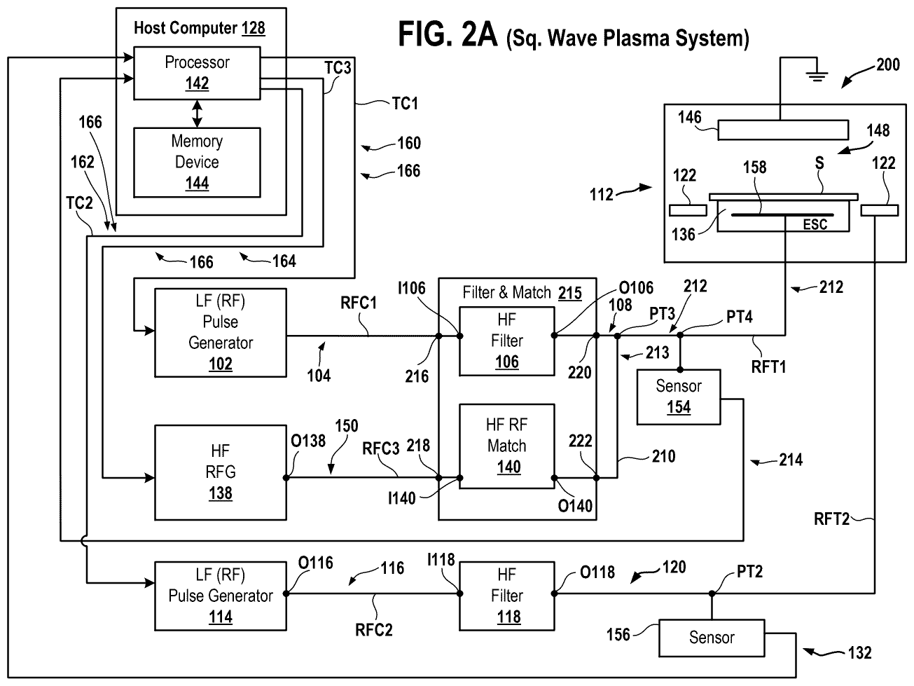

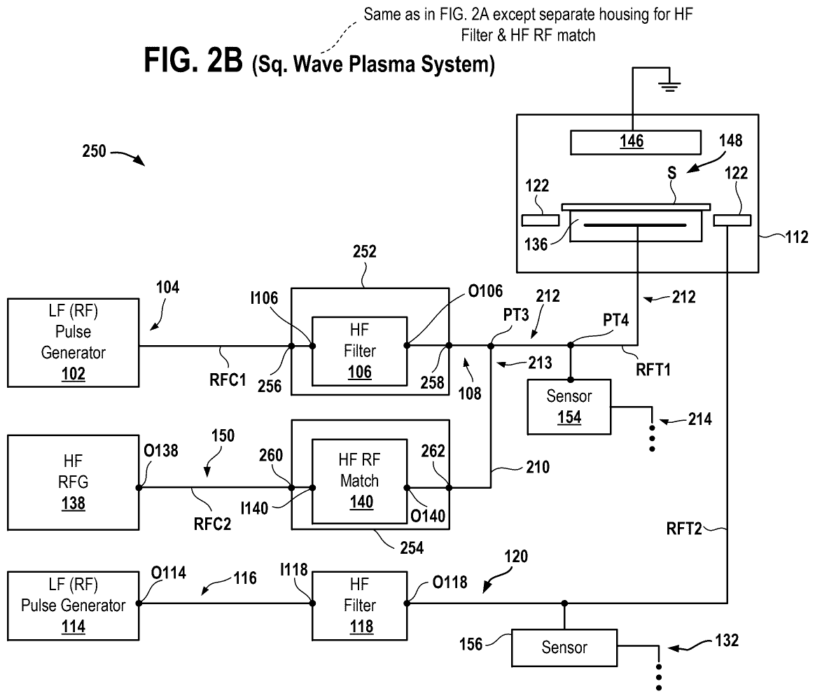

FIG. 2A is a diagram of an embodiment of a system 200 to illustrate generation of square waves for processing the substrate S. The system 200 is similar to the system 100 except that in the system 200, the upper electrode 146 is coupled to the reference potential and the lower electrode 158 is coupled via the HF RF match 140 to the HF RF generator 138.

The system 200 includes the host computer 128, the LF RF pulse generator 102, the HF RF generator 138, the LF RF pulse generator 114, a filter and match 215, the HF filter 118, and the sensors 154 and 156. The filter and match 215 includes the HF filter 106 and the HF RF match 140. For example, the filter and match 215 is a housing that encloses the HF filter 106 and the HF RF match 140. To illustrate, electrical circuit components of the HF filter 106 and the HF RF match 140 are surrounded by the housing of the filter and match 215. As an example, the housing of the filter and match 215 is fabricated from a metal, such as aluminum or an alloy of aluminum.

The RF cable RFC1 extends via a port 216 of the filter and match 215 to couple to the input I106. Also, the RF cable RFC3 extends via a port 218 of the filter and match 215 to couple to the input I140. Moreover, the RF transmission line RFT1 extends via a port 220 of the filter and match 215 to couple to the output O106. An RF connection 210 extends via a port 222 of the filter and match 215 to couple to the output O140. As an example, a port is an opening.

The output O140 of the HF RF match 140 is coupled via the RF connection 210 to a point PT3 on the RF rod of the RF transmission line RFT1. An example of the RF connection 210 includes an RF strap. Another example of the RF connection 210 includes two or more RF straps coupled to each other. Another example of the RF connection 210 includes a combination of one or more RF straps and an RF transmission line. To illustrate, a first RF strap of the RF connection 210 is coupled to the output O140 and to a first end of an RF rod of the RF transmission line. In the illustration, a second RF strap of the RF connection 210 is coupled to a second end of the RF rod and to the point PT3.

Also, the point PT3 is coupled to the output O106 of the HF filter 106. The sensor 154 is coupled to a point PT4 on the RF rod of the RF transmission line RFT1. The point PT4 is located between the point PT3 and the lower electrode 158.

In operation, the HF RF match 140 matches an impedance of a load coupled to the output O140 with an impedance of the source coupled to the input I140. An example of the load coupled to the output O140 includes the RF connection 210, a portion of the RF transmission line RFT1 between the point PT3 and the lower electrode 158, and the plasma chamber 112. The impedances are matched to output a modified RF signal 213 at the output O140.

The modified RF signal 213 is transferred via the RF connection 210 from the output O140 to the point PT4. The filter output signal 108 is combined, such as summed or added, with the modified RF signal 213 at the point PT4 to output a combined signal 212 at the point PT4. For example, a magnitude of the filter output signal 108 is added to a magnitude of the modified RF signal 213 at the point PT4. The combined signal 212 is transferred from the point PT4 via a portion of the RF rod of the RF transmission line RFT1 between the point PT3 and the lower electrode 158 to the lower electrode 158.

When the combined signal 212 is supplied to the lower electrode 158, the filter output signal 120 is supplied to the edge ring 122, and the one or more process gases are supplied to the gap 148 to process the substrate S, the sensor 154 measures a parameter of the combined signal 212 at the point PT4 to generate a parameter signal 214. For example, a parameter of the parameter signal 214 is the same as the parameter of the combined signal 212. To illustrate, a frequency of the parameter signal 214 is the same as a frequency of the combined signal 212, a phase of the parameter signal 214 is the same as a phase of the combined signal 212, and a magnitude of the parameter signal 214 is the same a magnitude of the combined signal 212. As another example, both the combined signal 212 and the parameter signal 214 are square wave signals. The parameter signal 214 is sent from the sensor 154 to the processor 142.

The processor 142 determines whether the parameter of the parameter signal 214 is within a predetermined range from a predetermined parameter. For example, the processor 142 applies a Fourier transform to the parameter signal 214 to determine a band of frequencies. The processor 142 further calculates a statistical value, such as a moving average or a moving median, from the frequencies of the band to determine a frequency of the parameter signal 214. In the example, the processor 142 determines whether the frequency of the parameter signal 214 is within a predetermined frequency range from a predetermined frequency. Further, in the example, the processor 142 determines whether a phase of the parameter signal 214 is within a predetermined phase range from a predetermined phase. In the example, the processor 142 determines the phase of the parameter signal 214 by determining a time at which a magnitude of the parameter signal 214 is at a predetermined parameter value. Also, in the example, the processor 142 determines a magnitude of the parameter signal 214, and determines whether the magnitude is within a predetermined magnitude range from a predetermined magnitude.

Upon determining that the parameter of the parameter signal 214 is within the predetermined range from the predetermined parameter, the processor 142 determines not to modify a parameter of the square wave signal 104 that is generated by the LF RF pulse generator 102, or a parameter of the RF signal 150 generated by the HF RF generator 138, or both the parameters. For example, in response to determining that the frequency of the parameter signal 214 is within the predetermined frequency range from the predetermined frequency, the phase of the parameter signal 214 is within the predetermined phase range from the predetermined phase, and the magnitude of the parameter signal 214 is within the predetermined magnitude range from the predetermined magnitude, the processor 142 determines not to change the parameter of the square wave signal 104 and not to change the parameter of the RF signal 150. To illustrate, the processor 142 does not generate the additional instruction signal different from the instruction signal 160 and does not generate a next instruction signal different from the instruction signal 164. For example, the processor 142 does not generate the next instruction signal that includes a different parameter than that included within the instruction signal 164. As such, the LF RF pulse generator 102 continues to generate and send the square wave signal 104 and the HF RF generator 138 continues to generate and send the RF signal 150.

On the other hand, in response to determining that the parameter of the parameter signal 214 is not within the predetermined range from the predetermined parameter, the processor 142 determines to modify the parameter of the square wave signal 102 or the parameter of the RF signal 150 or both the parameters. For example, in response to determining that the frequency of the parameter signal 214 is not within the predetermined frequency range from the predetermined frequency, or the phase of the parameter signal 214 is not within the predetermined phase range from the predetermined phase, or the magnitude of the parameter signal 214 is not within the predetermined magnitude range from the predetermined magnitude, the processor 142 determines to change the parameter of the square wave signal 102 or the parameter of the RF signal 150 or both the parameters.

To illustrate, the processor 142 generates the additional instruction signal or the next instruction signal or a combination thereof. In the illustration, the next instruction signal includes the different parameter than that included within the instruction signal 164. To further illustrate, in response to determining that the frequency of the parameter signal 214 is not within the predetermined frequency range from the predetermined frequency, the processor 142 determines to change the frequency of the square wave signal 104 or the frequency of the RF signal 150 or a combination thereof. Also, upon determining that the phase of the parameter signal 214 is not within the predetermined phase range from the predetermined phase, the processor 114 determines to change the phase of the square wave signal 104 or the phase of the RF signal 150 or a combination thereof. Moreover, in response to determining that the magnitude of the parameter signal 210 is not within the predetermined magnitude range from the predetermined magnitude, the processor 142 determines to change the magnitude of the square wave signal 104 or the magnitude of the RF signal 150 or a combination thereof.

Upon receiving the next instruction signal from the processor 142 regarding changing the RF signal 150, the HF RF generator 138 generates a next RF signal based on the different parameter. In this manner, the processor 142 continues to control the LF RF pulse generator 102 or the HF RF generator 138 or both the LF RF pulse generator 102 and the HF RF generator 138 until a parameter of a parameter signal received from the sensor 154 is within the predetermined range from the predetermined parameter.

In one embodiment, the RF connection 210 is located within the filter and match 215. In the embodiment, the point PT3 is located within the filter and match 215 or located at the same location as that of the port 220. For example, the point PT3 of connection between the RF connection 210 and the RF rod of the RF transmission line RFT1 is surrounded by the port 220.

FIG. 2B is a diagram of an embodiment of a system 250. The system 250 is similar to the system 200 except that in the system 250, the HF filter 106 is located within a filter housing 252 and the HF RF match 140 is located within a match housing 254. As an example, each housing 252 and 254 is fabricated from a metal, such as aluminum or an alloy of aluminum. It should be noted that the host computer 128 is not shown in the system 250 to not clutter FIG. 2B.

The RF cable RFC1 extends via a port 256 of the filter housing 252 to couple to the input I106. Also, the RF transmission line RFT1 extends via a port 258 of the filter housing 252 to couple to the output O106. Similarly, the RF cable RFC2 extends via a port 260 of the match housing 254 to couple to the input I140. Also, the RF connection 210 extends via a port 262 of the match housing 254 to couple to the output O140. Functionality of the system 250 is the same as that described above with reference to the system 200.

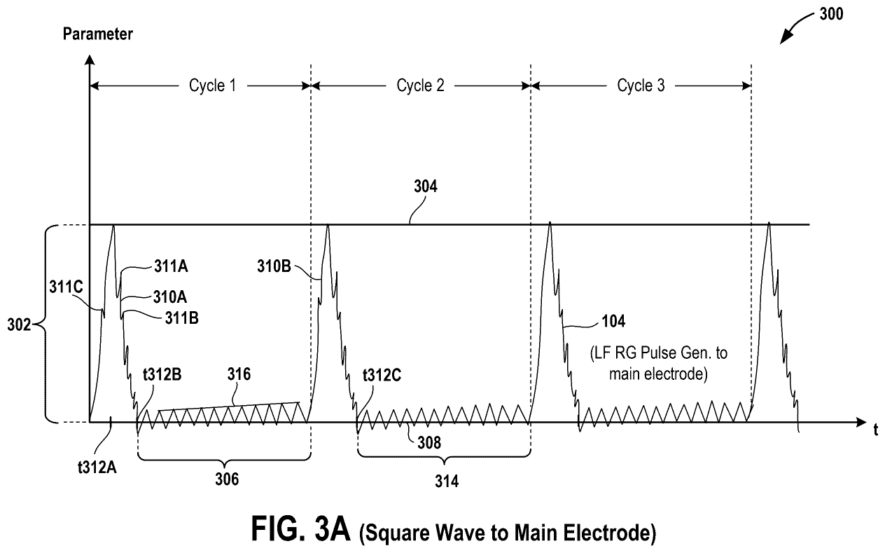

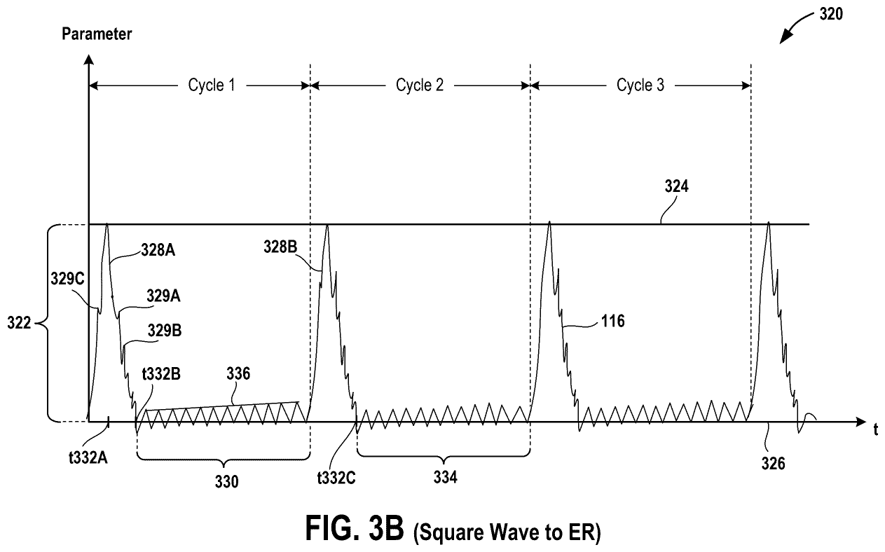

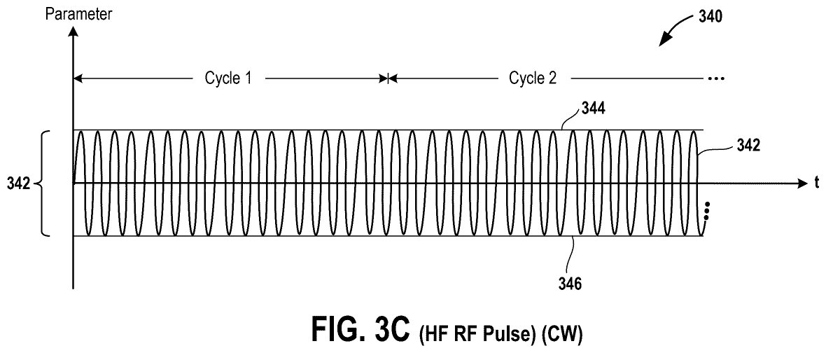

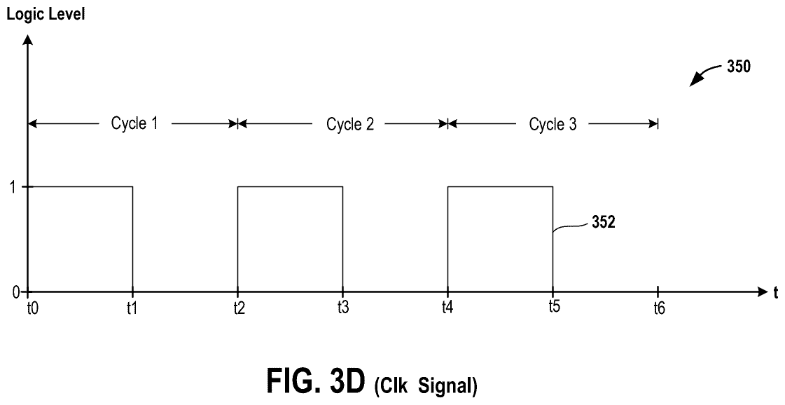

FIG. 3A is an embodiment of a graph 300 to illustrate the square wave signal 104 that is generated by the LF RF pulse generator 102 (FIG. 1). The graph 300 includes the parameter of the square wave signal 104 versus time t. The parameter of the square wave signal 104 is plotted on a y-axis and the time t is plotted on an x-axis.

The square wave signal 104 has a peak-to-peak amplitude 302, which is an amplitude between a maximum value 304 of the square wave signal 104 and a minimum value 308 of the square wave signal 104. The peak-to-peak amplitude 302 is a difference between the maximum value 304 and the minimum value 308. As an example, the peak-to-peak amplitude 302 ranges between 8 kilovolts (kV) and 10 kV.

During each cycle of a clock signal, a main pulse of the square wave signal 104 occurs. For example, during a first cycle, such as a cycle 1, of the clock signal, a main pulse 310A occurs. In the example, during a second cycle, such as a cycle 2, of the clock signal, another main pulse 310B occurs.

It should be noted that during each cycle of the clock signal, a main pulse of the square wave signal 104 is followed by small fluctuations of voltage. For example, during the first cycle, a main pulse 310A is followed by small fluctuations of voltage 306. During the second cycle, a main pulse 310B is followed by small fluctuations of voltage 314. An example of each small fluctuation is a small variation or a small waveform or a sinusoidal waveform or a sinusoidal RF waveform. Small fluctuations of voltage are sometimes referred to herein as voltage fluctuations. As another example, during each cycle of the clock signal, a peak-to-peak amplitude of voltage fluctuations of the square wave signal 104 is less than a peak-to-peak amplitude of a main pulse of the square wave signal 104.

It should further be noted that each voltage fluctuation of the square wave signal 104 has a similar shape, such as a sinusoidal shape. For example, each voltage fluctuation of the square wave signal 104 is a sinusoidal waveform. Also, as an example, each main pulse of the square wave signal 104 has a nearly triangular shape or a saw-tooth shape. To illustrate, the main pulse 310A has a triangular shape in which two sides of the triangle has variations that form local peaks. To further illustrate, the main pulse 310A has a local peak 311A and a local peak 311B formed by its first side and has a local peak 311C formed by its second side. The local peaks of a main pulse of the square wave signal 104 have lower amplitudes than the maximum value 304 of the square wave signal 104.

Moreover, each main pulse of the square wave signal 104 during a cycle of the clock signal has a maximum value, which is substantially greater than a maximum value of voltage fluctuations that occur during the cycle. For example, the main pulse 310A has a maximum value that is between seven to ten times larger than a maximum value 316 of the voltage fluctuations 306.

The square wave signal 104 includes multiple square waves, and each square wave occurs during a corresponding cycle of the clock signal. For example, a square wave of the square wave signal 104 includes a main pulse followed by small fluctuations of voltage.

In an embodiment, a frequency of the square wave signal 104 is a statistical value, such as a moving average or a moving median, of frequencies of voltage fluctuations and main pulses of the square wave signal 104. For example, a frequency of the square wave signal 104 is a moving average of frequencies of the voltage fluctuations 306 and 314 and the main pulses 310A and 310B.

In one embodiment, a phase of the square wave signal 104 during a cycle of the clock signal is a time at which a main pulse of the square wave signal 104 has a predetermined magnitude. For example, a phase of the square wave signal 104 during the cycle 1 is a time t312A at which the main pulse 310A during the cycle 1 has the maximum magnitude, such as the maximum value. As another example, a phase of the square wave signal 104 during the cycle 1 is a time at which a magnitude of the square wave signal 104 is zero.

In an embodiment, a phase of the square wave signal 104 is a statistical value, such as a moving average or a moving median, of all phases of the square wave signal 104 during a predetermined number of cycles of the clock signal. For example, a phase of the square wave signal 104 over the cycles 1 and 2 is a moving average of times t312B and t312C at which the main pulses 310A and 310B have the same magnitude, such as zero. The times t312B and t312C are normalized for calculating the moving average. To illustrate, a time interval between a start time of the cycle 1 and the time t312B is coincides with a time interval between a start time of the cycle 2 and the time 312C to normalize the times t312B and t312C.

In an embodiment, a magnitude of the square wave signal 104 is the peak-to-peak amplitude 302 of the square wave signal 104.

It should further be noted that in one embodiment, the maximum value 304 is a statistical value, such as a moving average or a moving median, generated based on maximum values of main pulses of the square wave signal 104 during the predetermined number of cycles of the clock signal. For example, the maximum value 304 is an average of maximum values of the main pulses 310A and 310B. In the example, the maximum value 304 changes to an average of the maximum value of the main pulse 310B and a maximum value of a main pulse of the square wave signal 104 during a cycle 3 of the clock signal. It should be noted that the cycle 2 of the clock signal is consecutive to the cycle 1 of the clock signal and the cycle 3 of the clock signal is consecutive to the cycle 2.

Similarly, in the embodiment, the minimum value 308 is a statistical value, such as a moving average or a moving median, generated based on minimum values of the square wave signal 104 during the predetermined number of cycles. For example, the minimum value 308 is an average of minimum values of the voltage fluctuations 306 and the main pulse 310A. As another example, the minimum value 308 is an average of minimum values of the voltage fluctuations 314 and the main pulse 310B.

FIG. 3B is an embodiment of a graph 320 to illustrate the square wave signal 116 that is generated by the LF RF pulse generator 114 (FIG. 1). The graph 320 includes the parameter of the square wave signal 116 versus the time t. The parameter of the square wave signal 116 is plotted on a y-axis and the time t is plotted on an x-axis.

The square wave signal 116 has a peak-to-peak amplitude 322, which is an amplitude between a maximum value 324 of the square wave signal 116 and a minimum value 326 of the square wave signal 116. The peak-to-peak amplitude 322 is a difference between the maximum value 324 and the minimum value 326. As an example, the peak-to-peak amplitude 322 ranges between 7 kV and 10 kV.

During each cycle of the clock signal, a main pulse of the square wave signal 116 occurs. For example, during the first cycle, a main pulse 328A occurs and during the second cycle, another main pulse 328B occurs.

It should be noted that during each cycle of the clock signal, a main pulse is followed by multiple voltage fluctuations of the square wave signal 116. For example, during the first cycle, voltage fluctuations 330 of the square wave signal 116 immediately follow the main pulse 328A of the square wave signal 116. During the second cycle, multiple voltage fluctuations 334 of the square wave signal 116 immediately follow the main pulse 328B of the square wave signal 116. As another example, during each cycle of the clock signal, a peak-to-peak amplitude of voltage fluctuations of the square wave signal 116 is less than a peak-to-peak amplitude of a main pulse of the square wave signal 116.

It should further be noted that each voltage fluctuation of the square wave signal 116 has a similar shape, such as a sinusoidal shape. For example, each voltage fluctuation of the square wave signal 116 is a sinusoidal waveform. Also, each main pulse of the square wave signal 116 has nearly triangular shape or a saw-tooth shape. To illustrate, the main pulse 328A has a triangular shape in which two sides of the triangle has variations that form local peaks. To further illustrate, the main pulse 328A has a local peak 329A and a local peak 329B formed by its first side and has a local peak 329C formed by its second side. The local peaks of a main pulse of the square wave signal 116 have lower amplitudes than the maximum value 324 of the square wave signal 116.

Moreover, each main pulse of the square wave signal 116 during a cycle of the clock signal has a maximum value, which is substantially greater than a maximum value of voltage fluctuations that occur during the cycle. For example, the main pulse 328A has a maximum value that is between seven to ten times larger than a maximum value 336 of the voltage fluctuations 330.

In an embodiment, a frequency of the square wave signal 116 is a statistical value, such as a moving average or a moving median, of frequencies of voltage fluctuations and main pulses of the square wave signal 116. For example, a frequency of the square wave signal 116 is a moving average of frequencies of the voltage fluctuations 330 and 334 and the main pulses 328A and 328B.

In one embodiment, a phase of the square wave signal 116 during a cycle of the clock signal is a time at which a main pulse during the cycle has a predetermined magnitude. For example, a phase of the square wave signal 116 during the cycle 1 is a time t332A at which the main pulse 328A during the cycle 1 has the maximum magnitude, such as the maximum value. As another example, a phase of the square wave signal 116 during the cycle 1 is a time at which a magnitude of the square wave signal 116 is zero.

In an embodiment, a phase of the square wave signal 116 is a statistical value, such as a moving average or a moving median, of all phases during a predetermined number of cycles of the clock signal. For example, a phase of the square wave signal 116 over the cycles 1 and 2 is a moving average of times t332B and t332C at which the main pulses 328A and 328B have their same magnitude, such as zero. The times t332B and t332C are normalized for calculating the moving average. To illustrate, a time interval between a start time of the cycle 1 and the time t332B is coincides with a time interval between a start time of the cycle 2 and the time 332C to normalize the times t332B and t332C.

In an embodiment, a magnitude of the square wave signal 116 is the peak-to-peak amplitude 322 of the square wave signal 116.

It should further be noted that in one embodiment, the maximum value 324 is a statistical value, such as a moving average or a moving median, generated from maximum values of main pulses of the square wave signal 116 during the predetermined number of cycles of the clock signal. For example, the maximum value 324 is an average of maximum values of the main pulses 328A and 328B. In the example, the maximum value 324 changes to an average of the maximum value of the main pulse 328B and a maximum value of a main pulse of the square wave signal 116 during the cycle 3.

Similarly, in the embodiment, the minimum value 326 is a statistical value, such as a moving average or a moving median, generated from minimum values of the square wave signal 116 during the predetermined number of cycles. For example, the minimum value 326 is an average of minimum values of the voltage fluctuations 330 and the main pulse 328A. As another example, the minimum value 326 is an average of minimum values of the voltage fluctuations 334 and the main pulse 328B.

FIG. 3C is a diagram of an embodiment of a graph 340 to illustrate an RF signal 342 that is generated by the HF RF generator 138 (FIG. 1). The RF signal 342 is an example of the RF signal 150 (FIG. 1). The graph 340 includes the parameter of the RF signal 150 versus the time t. The parameter of the RF signal 342 is plotted on a y-axis and the time t is plotted on an x-axis.

The RF signal 342 has a peak-to-peak amplitude 342, which is an amplitude between a maximum value 344 of the RF signal 342 and a minimum value 346 of the RF signal 342. The peak-to-peak amplitude 342 is a difference between the maximum value 344 and the minimum value 346.

It should be noted that during each cycle of the clock signal, there are multiple sinusoidal waveforms of the RF signal 342. For example, there are no low peak-to-peak voltage waveforms and high peak-to peak voltage main pulses during each cycle. As another example, each sinusoidal waveform of the RF signal 342 has a similar shape, such as a sinusoidal shape.

It should further be noted that in one embodiment, the maximum value 344 is a statistical value, such as a moving average or a moving median, generated from maximum values of the RF signal 342 during a predetermined number of cycles of the clock signal. For example, the maximum value 344 is an average of maximum values of sinusoidal waveforms of the RF signal 342 during the cycle 1. In the example, the maximum value 344 changes to an average of the maximum values of sinusoidal waveforms of the RF signal 342 during a cycle 2, and further changes to an average of the maximum values of sinusoidal waveforms of the RF signal 342 during the cycle 3.

Similarly, in the embodiment, the minimum value 346 is a statistical value, such as a moving average or a moving median, generated from minimum values of the RF signal 342 during the predetermined number of cycles. For example, the minimum value 346 is an average of minimum values of the sinusoidal waveforms of the RF signal 342 during the cycle 1. As another example, the minimum value 346 is an average of minimum values of the sinusoidal waveforms of the RF signal 342 during the cycle 2.

FIG. 3D is an embodiment of a graph 350 to illustrate a clock signal 352. The graph 350 plots a logic level of the clock signal 352 on a y-axis and the time t on an x-axis. The time t includes a time t0, t2, t3, t4, t5, t6, and so on in a consecutive order of occurrence. The clock signal 352 periodically transitions between a logic level 1 and a logic level 0. For example, during the cycle 1 of the clock signal 352, the clock signal 352 transitions from the logic level 0 to the logic level 1 at the time t0 and transitions from the logic level 1 to the logic level 0 at the time t1. During the cycle 2 of the clock signal 352, the clock signal 352 transitions from the logic level 0 to the logic level 1 at the time t2 and transitions from the logic level 1 to the logic level 0 at the time t3.

The clock signal 352 is generated by the processor 142 and supplied to the LF RF pulse generators 102 and 114 (FIG. 1) and to the HF RF generator 138 (FIG. 1). The generators 102, 114, and 138 operate in synchronization with the clock cycles of the clock signal 352.

In one embodiment, a controller of an LF RF pulse generator generates the clock signal 352 and supplies the clock signal to the other generators. For example, the controller of the LF RF pulse generator 102 generates the clock signal 352 and sends the clock signal 352 via one or more transfer cables to the LF RF pulse generator 114 and to the HF RF pulse generator 138.

In an embodiment, a controller including a digital signal processor of the HF RF generator 138 generates the clock signal. The controller of the HF RF generator 138 supplies the clock signal 352 via one or more transfer cables to the LF RF pulse generators 102 and 114.

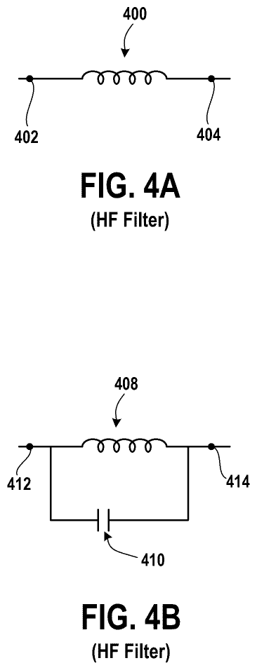

FIG. 4A is an embodiment of an inductor 400, which is an example of the HF filter 106 or 118 (FIG. 1). The inductor 400 has an end 402 and another end of 404. The end 402 is an example of the input I106 or I118 (FIG. 1). Also, the end 404 is an example of the input output O106 or O118 (FIG. 1).

FIG. 4B is an embodiment of a parallel circuit 406, which is an example of the HF filter 106 or 118 (FIG. 1). The parallel circuit 406 includes an inductor 408 and a capacitor 410. The inductor 408 is coupled in parallel with the capacitor 410. The parallel circuit 406 has an end 412 and another end 414. The end 412 is an example of the input I106 or I118 (FIG. 1). Also, the end 414 is an example of the input output O106 or O118 (FIG. 1).

In one embodiment, the HF filter 106 or 118 includes one or more inductors and one or more capacitors. The one or more inductors are coupled in parallel with the one or more capacitors.

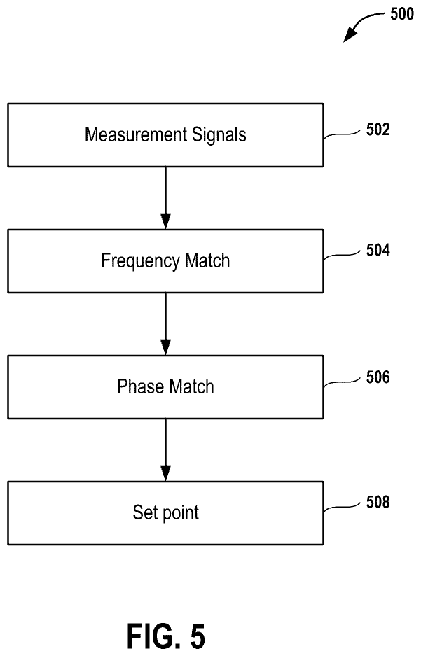

FIG. 5 is a flowchart to illustrate an embodiment of a method 500 for achieving uniformity across a surface of the substrate S (FIG. 1). The method 500 includes an operation 502. In the operation 502, the processor 142 receives the parameter signals 130 and 132 (FIG. 1) from the sensors 154 and 156 (FIG. 1) or receives the parameter signals 214 and 132 from the sensors 154 and 156 (FIG. 2A).

The method includes an operation 504 of frequency matching. For example, in the operation 504, the processor 142 determines whether the frequency of the parameter signal 132 is within a predetermined range from the frequency of the parameter signal 130. To illustrate, the processor 142 determines whether the frequency of the parameter signal 132 is within ±2 percent or ±5 percent from the frequency of the parameter signal 130. In the example, upon determining that the frequency of the parameter signal 132 is within the predetermined range from the frequency of the parameter signal 130, the processor 142 does not modify the frequency of the square wave signal 104 and the frequency of the square wave signal 116 (FIG. 1).

On the other hand, in the example, in response to determining that the frequency of the parameter signal 132 is not within the predetermined range from the frequency of the parameter signal 130, the processor 142 modifies the frequency of the square wave signal 104 or the frequency of the square wave signal 116 or a combination thereof. In the example, the frequency of the square wave signal 104 or the frequency of the square wave signal 116 or a combination thereof are modified until a frequency of a parameter signal received from the sensor 156 is within the predetermined range from a frequency of a parameter signal received from the sensor 154. To illustrate, upon determining that the frequency of the parameter signal 132 is not within the predetermined range from the frequency of the parameter signal 130, the processor 142 sends an instruction signal to the LF RF pulse generator 102 or 114 to tune, such as slightly modify, a frequency of operation of the LF RF pulse generator. In the illustration, the frequency of operation of the LF RF pulse generator is modified slightly from 400 kHz to be 400 kHz±5%. In the illustration, upon receiving the tuned frequency of operation, the LF RF generator generates a square wave signal having the tuned frequency of operation.

As another example, in the operation 504, the processor 142 determines whether the frequency of the parameter signal 132 is within the predetermined range from the frequency of the parameter signal 214. In the example, upon determining that the frequency of the parameter signal 132 is within the predetermined range from the frequency of the parameter signal 214, the processor 142 does not modify the frequency of the square wave signal 104, the frequency of the RF signal 150, and the frequency of the square wave signal 116 (FIG. 2A). On the other hand, in the example, in response to determining that the frequency of the parameter signal 132 is not within the predetermined range from the frequency of the parameter signal 214, the processor 142 modifies the frequency of the square wave signal 104, or the frequency of the RF signal 150, or the frequency of the square wave signal 116, or a combination of two or more thereof. In the example, the frequency of the square wave signal 104, or the frequency of the RF signal 150, or the frequency of the square wave signal 116, or a combination of two or more thereof are modified until a frequency of a parameter signal received from the sensor 156 is within the predetermined range from a frequency of a parameter signal received from the sensor 154. To illustrate, upon determining that the frequency of the parameter signal 132 is not within the predetermined range from the frequency of the parameter signal 214, the processor 142 sends an instruction signal to the generator 102 or 114 or 138 to tune, such as slightly modify or modify within a predetermined range, a frequency of operation of the generator. In the illustration, the frequency of operation of the LF RF pulse generator 102 or 114 is modified slightly from 400 kHz to be 400 kHz±5%, or the frequency of operation of the HF RF generator 138 is modified slightly from 60 MHz to 60 MHz±5%. In the illustration, upon receiving the tuned frequency of operation, the generator generates a signal having the tuned frequency of operation.

The method 500 further includes an operation 506 of phase matching. For example, in the operation 506, the processor 142 determines whether a phase of the parameter signal 132 is within a predetermined range from a phase of the parameter signal 130 (FIG. 1). To illustrate, the processor 142 determines whether the phase of the parameter signal 132 is within ±2 percent or ±5 percent from the phase of the parameter signal 130. In the example, upon determining that the phase of the parameter signal 132 is within the predetermined range from the phase of the parameter signal 130, the processor 142 does not modify the phase of the square wave signal 104 and the phase of the square wave signal 116 (FIG. 1). On the other hand, in the example, in response to determining that the phase of the parameter signal 132 is not within the predetermined range from the phase of the parameter signal 130, the processor 142 modifies the phase of the square wave signal 104 or the phase of the square wave signal 116 or a combination thereof. In the example, the phase of the square wave signal 104 or the phase of the square wave signal 116 or a combination thereof are modified until a phase of a parameter signal received from the sensor 156 is within the predetermined range from a phase of a parameter signal received from the sensor 154.

As an illustration of modifying a phase, the processor 142 generates another synchronization signal, different from the synchronization signal 166 (FIG. 1), and sends the other synchronization signal via the transfer cable TC2 to the LF RF pulse generator 114. The other synchronization signal is sent to the LF RF pulse generator 114 instead of the synchronization signal 166 and is sent within a predetermined time period from a time at which the synchronization signal 166 is sent to the LF RF pulse generator 102 to change the phase of the parameter signal received from the sensor 156 to be within the predetermined range from the phase of the parameter signal received from the sensor 154. An example of the predetermined time period is a predetermined number of time units, such as microseconds or milliseconds, from the time at which the synchronization signal 166 is sent to the LF RF pulse generator 102. Upon receiving the other synchronization signal, the LF RF pulse generator 114 generates a square wave signal. In this manner, the LF RF pulse generator 114 generates a square wave signal until a phase of a parameter signal received from the sensor 156 is within the predetermined range from a phase of a parameter signal received from the sensor 154. As another illustration, the other synchronization signal is sent from the processor 142 via the transfer cable TC1 to the LF RF pulse generator 102 instead of being sent via the transfer cable TC2 to the LF RF pulse generator 114. In the illustration, the synchronization signal 166 is sent to the LF RF pulse generator 114. Continuing with the illustration, upon receiving the other synchronization signal, the LF RF pulse generator 102 generates a square wave signal. In this manner, in the illustration, the LF RF pulse generator 102 generates a square wave signal until a phase of a parameter signal received from the sensor 156 is within the predetermined range from a phase of a parameter signal received from the sensor 154.

As another example, in the operation 506, the processor 142 determines whether the phase of the parameter signal 132 is within the predetermined range from the phase of the parameter signal 214 (FIG. 2A). In the example, upon determining that the phase of the parameter signal 132 is within the predetermined range from the phase of the parameter signal 214, the processor 142 does not modify the phase of the square wave signal 104, the phase of the RF signal 150, and the phase of the square wave signal 116 (FIG. 2A). On the other hand, in the example, in response to determining that the phase of the parameter signal 132 is not within the predetermined range from the phase of the parameter signal 214, the processor 142 modifies the phase of the square wave signal 104, or the phase of the RF signal 150, or the phase of the square wave signal 116, or a combination of two or more thereof. In the example, the phase of the square wave signal 104, or the phase of the RF signal 150, or the phase of the square wave signal 116, or a combination of two or more thereof is modified until a phase of a parameter signal received from the sensor 156 is within the predetermined range from a phase of a parameter signal received from the sensor 154.

As an illustration of modifying a phase, the processor 142 generates the other synchronization signal, different from the synchronization signal 166, and sends the other synchronization signal via the transfer cable TC3 to the HF RF generator 138. The other synchronization signal is sent to the HF RF generator 138 instead of the synchronization signal 166 and is sent within the predetermined time period from a time at which the synchronization signal 166 is sent to the LF RF pulse generators 102 and 114 to change the phase of the parameter signal received from the sensor 156 to be within the predetermined range from the phase of the parameter signal received from the sensor 154. Upon receiving the other synchronization signal, the HF RF generator 138 generates an RF signal. In this manner, the HF RF generator 138 generates an RF signal until a phase of a parameter signal received from the sensor 156 is within the predetermined range from a phase of a parameter signal received from the sensor 154. As another illustration, the other synchronization signal is sent from the processor 142 via the transfer cable TC1 to the LF RF pulse generator 102 or via the transfer cable TC2 to the LF RF pulse generator 114 instead of being sent via the transfer cable TC3 to the HF RF generator 138.

The method 500 further includes an operation 508 of setpoint matching. For example, the processor 142 determines from the magnitudes, such as peak-to-peak amplitudes or zero-to-peak amplitudes, of the parameters of the parameter signals 132 and 130 (FIG. 1) whether the LF RF pulse generator 102 is operating at a predetermined set point or the LF RF pulse generator 114 is operating at a predetermined set point. To illustrate, the processor 142 determines whether the magnitude of the parameter of the parameter signal 132 is within a predetermined range from a magnitude of the parameter of the parameter signal 130. In the illustration, the predetermined range is ±5 percent or ±3 percent. Continuing further with the illustration, in response to determining that the magnitude of the parameter of the parameter signal 132 is not within the predetermined range from the magnitude of the parameter of the parameter signal 130, the processor 142 modifies, such as increases or decreases, the magnitude of the parameter of the square wave signal 116 (FIG. 1) to provide a modified magnitude, and sends the modified magnitude via the transfer cable TC2 to the LF RF pulse generator 114. In the illustration, upon receiving the modified magnitude, the LF RF pulse generator 114 generates a square wave signal having the modified magnitude. In this manner, in the illustration, the LF RF pulse generator 114 continues to modify a magnitude of a square wave signal generated by the LF RF pulse generator 114 until a magnitude of a parameter of a parameter signal received from the sensor 156 is within the predetermined range from a magnitude of a parameter of a parameter signal received from the sensor 154. On the other hand, in the illustration, in response to determining that the magnitude of the parameter of the parameter signal 132 is within the predetermined range from the magnitude of the parameter of the parameter signal 130, the processor 142 determines that the LF RF pulse generator 102 is operating at the predetermined set point and the LF RF pulse generator 114 is operating at the predetermined set point. As an example, the predetermined set point of operation of the LF RF pulse generator 102 is equal to the predetermined set point of operation of the LF RF pulse generator 114. As another example, the predetermined set point of operation of the LF RF pulse generator 102 is different from the predetermined set point of operation of the LF RF pulse generator 114.

As another example, instead of modifying the magnitude of the parameter of the square wave signal 116, the processor 142 modifies a magnitude of the parameter of the square wave signal 104 until a magnitude of a parameter of a parameter signal received from the sensor 156 is within the predetermined range from a magnitude of a parameter of a parameter signal received from the sensor 154. To illustrate, the processor 142 determines whether the magnitude of the parameter of the parameter signal 132 is within the predetermined range from a magnitude of the parameter of the parameter signal 130. In the illustration, the predetermined range is ±5 percent or ±3 percent. Continuing further with the illustration, in response to determining that the magnitude of the parameter of the parameter signal 132 is not within the predetermined range from the magnitude of the parameter of the parameter signal 130, the processor 142 modifies, such as increases or decreases, the magnitude of the parameter of the square wave signal 104 (FIG. 1) to provide a modified magnitude, and sends the modified magnitude via the transfer cable TC1 to the LF RF pulse generator 102. In the illustration, upon receiving the modified magnitude, the LF RF pulse generator 102 generates a square wave signal having the modified magnitude. In this manner, in the illustration, the LF RF pulse generator 102 continues to modify a magnitude of a square wave signal generated by the LF RF pulse generator 102 until a magnitude of a parameter of a parameter signal received from the sensor 156 is within the predetermined range from a magnitude of a parameter of a parameter signal received from the sensor 154.

As yet another example, the processor 142 determines from the magnitudes of the parameters of the parameter signals 132 and 214 (FIG. 2A) whether the LF RF pulse generator 102 is operating at a predetermined set point or the LF RF pulse generator 114 is operating at a predetermined set point or the HF RF generator 138 is operating at a predetermined set point. To illustrate, the processor 142 determines whether the magnitude of the parameter of the parameter signal 132 is within a predetermined range from a magnitude of the parameter of the parameter signal 214. In the illustration, the predetermined range is ±5 percent or ±3 percent. Continuing further with the illustration, in response to determining that the magnitude of the parameter of the parameter signal 132 is not within the predetermined range from the magnitude of the parameter of the parameter signal 214, the processor 142 modifies, such as increases or decreases, the magnitude of the parameter of the square wave signal 116 (FIG. 1) to provide a modified magnitude, and sends the modified magnitude via the transfer cable TC2 to the LF RF pulse generator 114. Upon receiving the modified magnitude, the LF RF pulse generator 114 generates a square wave signal having the modified magnitude. In this manner, the LF RF pulse generator 114 continues to modify a magnitude of a square wave signal generated by the LF RF pulse generator 114 until a magnitude of a parameter of a parameter signal received from the sensor 156 is within the predetermined range from a magnitude of a parameter of a parameter signal received from the sensor 154.

As another example, instead of modifying the magnitude of the parameter of the square wave signal 116, the processor 142 modifies a magnitude of the parameter of the square wave signal 104 or a magnitude of the parameter of the RF signal 150 until a magnitude of a parameter of a parameter signal received from the sensor 156 is within the predetermined range from a magnitude of a parameter of a parameter signal received from the sensor 154. To illustrate, the processor 142 determines whether the magnitude of the parameter of the parameter signal 132 is within the predetermined range from a magnitude of the parameter of the parameter signal 214. In the illustration, the predetermined range is ±5 percent or ±3 percent. Continuing further with the illustration, in response to determining that the magnitude of the parameter of the parameter signal 132 is not within the predetermined range from the magnitude of the parameter of the parameter signal 214, the processor 142 modifies, such as increases or decreases, the magnitude of the parameter of the RF signal 150 (FIG. 2A) to provide a modified magnitude, and sends the modified magnitude via the transfer cable TC3 to the HF RF generator 138. Upon receiving the modified magnitude, the HF RF generator 138 generates an RF signal having the modified magnitude. In this manner, the HF RF generator 138 continues to modify a magnitude of an RF signal generated by the HF RF generator 138 until a magnitude of a parameter of a parameter signal received from the sensor 156 is within the predetermined range from a magnitude of a parameter of a parameter signal received from the sensor 154. On the other hand, in response to determining that the magnitude of the parameter of the parameter signal 132 is within the predetermined range from the magnitude of the parameter of the parameter signal 214, the processor 142 determines that the LF RF pulse generator 102 is operating at the predetermined set point, the LF RF pulse generator 114 is operating at the predetermined set point, and the HF RF generator 138 is operating at the predetermined set point.

In one embodiment, the operations 504, 506, and 508 are performed in an order different than that illustrated in FIG. 5. For example, the operation 506 is performed before the operation 504. As another example, the portions 506 and 508 are performed before the operation 504. As yet another example, the operation 508 is performed first, the operation 506 is performed second, and the operation 502 is performed third.

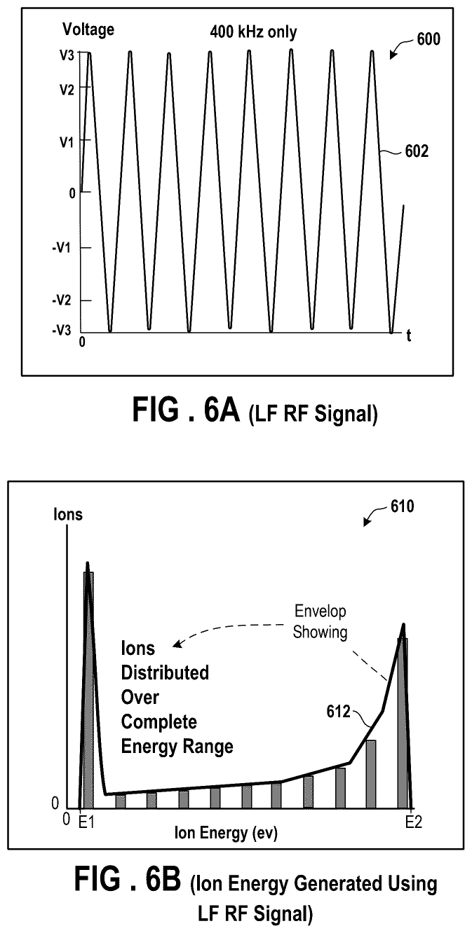

FIG. 6A is a diagram of an embodiment of a graph 600 to illustrate a plot 602 of a voltage of an RF signal that is generated by a 400 kHz RF generator versus the time t. The voltage is plotted on a y-axis and the time t on an x-axis. The RF signal generated by the 400 kHz RF generator is not a square wave signal. Rather, the RF signal generated by the 400 kHz RF generator is a sinusoidal signal. The voltage of the RF signal generated by the 400 kHz RF generator transitions periodically between a maximum magnitude V3 and a minimum magnitude −V3.

The magnitude V3 is greater than a magnitude V2 of the voltage of the RF signal. The voltage V2 is greater than a magnitude V1 of the RF signal. Also, the magnitude V1 is greater than zero. The magnitude of zero is greater than a magnitude −V1 of the RF signal. The magnitude −V1 is greater than a magnitude −V2 of the RF signal, and the magnitude −V2 is greater than the magnitude −V3.

FIG. 6B is a diagram of an embodiment of a graph 610 to illustrate a plot 612 of an envelope of the number of ions of plasma that is generated when the 400 kHz RF generator, illustrated with reference to FIG. 6A, is used. The envelope of the plot 612 illustrates a maximum number of ions of the plasma at a particular energy. The number of ions is plotted on a y-axis and ion energy, and electron volts (eV), is plotted on an x-axis. As shown, the ions are distributed across a range from an ion energy E1 to an ion energy E2. For example, there is a large number of ions of the plasma having the ion energy E1 and a large number of ions of the plasma having the ion energy E2. Also, there is a substantial amount of ions of plasma with energies between the ion energies E1 and E2.

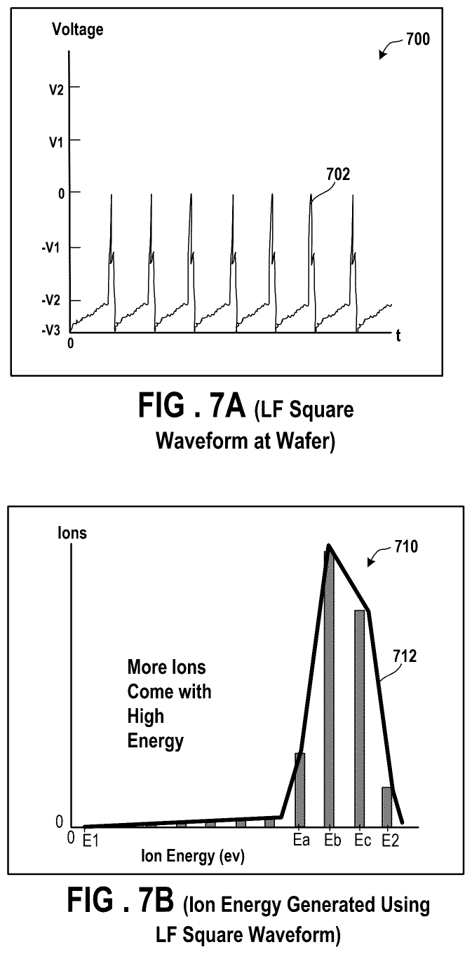

FIG. 7A is a diagram of an embodiment of a graph 700 to illustrate a plot of a voltage of a square wave signal 702 that is output as a parameter signal from a sensor. For example, the square wave signal 702 is output by the sensor 154 or 156 (FIG. 1). To illustrate, the square wave signal 702 is an example of the parameter signal 130 or 132 (FIG. 1). As another illustration, the square wave signal 702 is an example of the parameter signal 214 (FIG. 2A). The voltage is plotted on a y-axis and the time t on an x-axis in the graph 700. During each cycle of the clock signal 352 (FIG. 3D), the square wave signal 702 has multiple voltage fluctuations and a main pulse. The voltage of the square wave signal 702 has a peak-to-peak amplitude that ranges from a maximum of 0 volts to a minimum of −V3 volts.

FIG. 7B is a diagram of an embodiment of a graph 710 to illustrate a plot 712 of an envelope of the number of ions of plasma that is generated when an LF RF pulse generator that generates a square wave signal, illustrated with reference to FIG. 7A, is used. The number of ions is plotted on a y-axis and ion energy is plotted on an x-axis in the graph 710. As shown, the ions are distributed across the range from E1 to E2 electron volts. However, it should be noted that there is a large number of ions of the plasma having high ion energies. For example, large numbers of ions of the plasma have ion energies of Ea, Eb, Ec, and E2. The ion energies Ea-Ec are greater than the ion energy E1 but less than the ion energy E2. Because of the large numbers of ions, a rate of processing the substrate S with one or more square wave signals increases compared to a rate of processing the substrate S with one or more LF RF signals or with a combination of an LF RF signal and an HF RF signal.

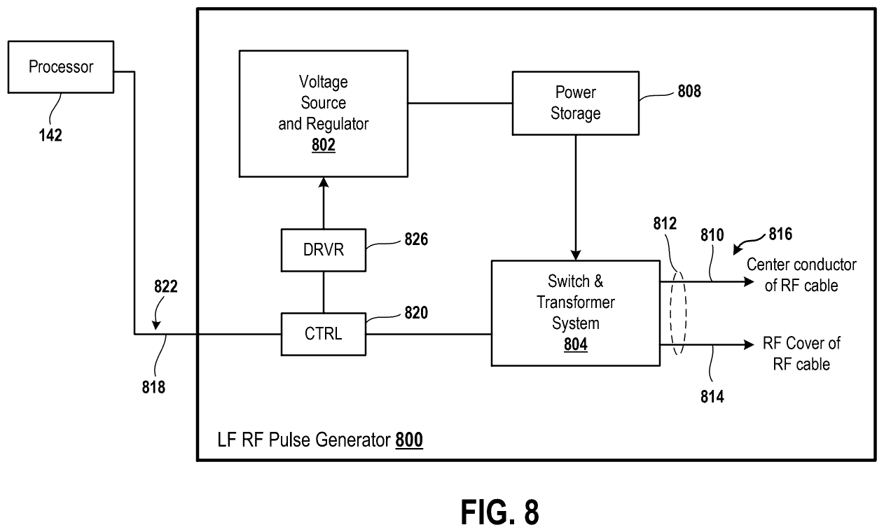

FIG. 8 is a diagram of an embodiment of an LF RF pulse generator 800. The LF RF pulse generator 800 is an example of the LF RF pulse generator 102 or 114 (FIGS. 1, 2A, and 2B). The LF RF pulse generator 800 includes a controller 820, a voltage source and regulator 802, a driver 826, a switch and transformer system 804, and a power storage 808. An example of the voltage source and regulator 802 includes a combination of a voltage supply, such as a direct current (DC) voltage supply, and a voltage regulator, such as a variable resistor. The voltage supply is coupled to the voltage regulator. An example of the switch and transformer system 804 includes a combination of a switch, such as a solid-state switch, and a transformer. An illustration of the solid-state switch is a transistor or a group of transistors. The solid-state switch is coupled to the transformer. As an example, the transformer includes a primary winding and a secondary winding. An example of the power storage 808 includes a capacitor. An example of the driver 826 is one or more transistors that are coupled to each other.

An example of the controller 820 includes a processor and a memory device. The processor of the controller 820 is coupled to the memory device of the controller 820. As another example, the controller 820 is an ASIC or a PLD.

The processor 142 is coupled to the controller 820 via a transfer cable 818. The transfer cable 818 is an example of the transfer cable TC1 or TC2 (FIG. 1). The controller 820 is coupled to the switch of the switch and transformer system 804 and is also coupled to the driver 826. The driver 826 is coupled to the voltage regulator of the voltage source and regulator 802. The voltage regulator of the voltage source and regulator 802 is coupled to the power storage 808.

Moreover, the power storage 808 is coupled to the transformer and the switch is coupled to the transformer. For example, the power storage 808 is coupled to a first end of the primary winding and the switch is coupled to a second end of the primary winding. A first end of the secondary winding of the transformer is coupled to a conductor 810 of an RF cable 812 and a second end of the secondary winding of the transformer is coupled to an RF cover 814 of the RF cable 812. The RF cable 812 is an example of the RF cable RFC1 or RFC2 (FIGS. 1 & 2A).

The voltage supply generates a voltage signal. The processor 142 controls the voltage regulator via the driver 826 to change, such as increase or decrease, a voltage of the voltage signal to output a modified voltage signal. A charge, based on a modified voltage of the modified voltage signal, is stored in the power storage 808. The controller 820 controls the switch to switch between an on state and an off state. In the off state, the switch opens and in the on state, the switch closes. The switch opens to disallow passage of energy of the charge stored in the power storage 808 to the transformer. The switch closes to allow passage of the energy to the transformer. During the on state of the switch, energy of the charge stored in the power storage 808 is discharged to the primary winding of the transformer. The charge stored within the power storage 808 may not be substantially drained during each on state, which allows for a higher pulse repetition frequency. For example, in one switch cycle, 5%-50% of the charge stored within the power storage 808 is drained. As yet another example, in one switch cycle, 1%-5% of the charge stored within the power storage 808 is drained. As an example, during a switch cycle, the switch turns on for a single time and turns off for a single time.

Voltage that is provided by the charge of the power storage 808 is transformed, such as increased or decreased, from the primary winding of the transformer to the secondary winding of the transformer to output a transformed voltage across the secondary winding of the transformer. The transformed voltage is of a square wave signal 816 that is provided from the transformer to the conductor 810. The square wave signal 816 is an example of the square wave signal 104 or 116 (FIGS. 1 & 2A).

The processor 142 generates and sends a frequency instruction signal to the processor of the controller 820 to generate the square wave signal 814. For example, the frequency instruction signal includes a first frequency for opening and closing the switch for generating a main pulse of the square wave signal 816 within each cycle of the clock signal 352. The frequency instruction signal further includes an indication that the switch be open and close at the first frequency for a single time during each cycle of the clock signal 352. In the example, the instruction signal further includes a second frequency for opening and closing the switch for generating voltage fluctuations of the square wave signal 816 within each cycle of the clock signal 352. Further, in the example, upon receiving the first and second frequencies, the processor of the controller 820 stores the first and second frequencies within the memory device of the controller 820. In response to receiving a trigger signal 822 via the transfer cable 818 from the processor 142, the processor of the controller 820 generates and sends a first current signal to the switch based on the first frequency and a second current signal to the switch based on the second frequency during each cycle of the clock signal 352. Also, in the example, the switch opens and closes according to the first and second frequencies during each cycle of the clock signal 352 to output a square wave signal. To illustrate, the switch opens and closes for a single time according to the first frequency to allow the LF RF pulse generator 800 to generate a single main pulse during each cycle of the clock signal 352. In the illustration, during each cycle of the clock signal 352, the switch opens and closes according to the second frequency to allow the LF RF pulse generator 800 to generate multiple voltage fluctuations during the cycle. The trigger signal 822 is an example of the synchronization signal 166 (FIG. 1) or the other synchronization signal, described herein.

Also, the processor 142 generates and sends the other synchronization signal to the controller 820 to alter a phase of the square wave signal 816. Upon receiving the other synchronization signal, the processor of the controller 820 controls the switch to turn off for a predetermined amount of time and turn on after the predetermined amount of time to change the phase of the square wave signal 816.

Furthermore, the processor 142 generates and sends a magnitude instruction signal to the controller 820 to change a magnitude of the square wave signal 816. For example, the magnitude instruction signal includes a peak-to-peak amplitude of the square wave signal 816 to be output from the LF RF pulse generator 800. In the example, the controller 820 stores the peak-to-peak amplitude in the memory device of the controller 820. Based on a correspondence between the peak-to-peak amplitude and a predetermined resistance of the voltage regulator, the processor of the controller 826 generates a command signal to achieve the predetermined resistance. The processor of the controller 826 sends the command signal to the driver 826. Further, in the example, upon receiving the command signal, the driver 826 generates a current signal to change a resistance of the voltage regulator to the predetermined resistance. The predetermined resistance corresponds to the modified voltage for charging the power storage 808. For example, when the voltage regulator has the predetermined resistance, the voltage regulator outputs the modified voltage. The driver 826 sends the current signal to the voltage regulator. Upon receiving the current signal, a resistance of the voltage regulator is modified to achieve the predetermined resistance. The amount of voltage supplied from the voltage supply via the voltage regulator to the power storage 808 is modified based on the predetermined resistance. The amount of voltage is modified to achieve the peak-to-peak amplitude of the parameter of the square wave signal 816.

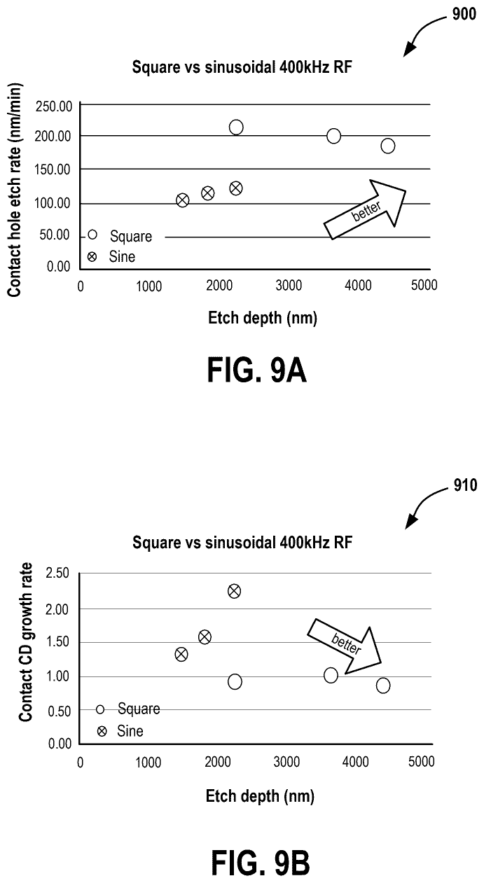

FIG. 9A shows an embodiment of a graph 900 to illustrate a comparison of contact hole etch rates between RF signals and square wave signals. For this comparison, maximum ion energies generated based on the RF signals and the square wave signals are matched. The graph 900 plots a contact hole etch rate on a y-axis and an etch depth on an x-axis. The contact hole etch rate is measured in nanometers per minute (nm/min) and the etch depth is measured in nanometers.

In the graph 900, contact hole etch rates for the square wave signals are greater compared to contact hole etch rates for the RF signals. The contact hole etch rates for the square wave signals are illustrated in FIG. 9A as circles and the contact hole etch rates for the RF signals are illustrated in FIG. 9A as circles with crosses (“X”s) in them. The greater etch rates are achieved with high energy plasma ions, such as plasma ions having the ion energies Ea through E2 (FIG. 7B). The greater etch rates facilitate achieving greater etch depths compared to those achieved using the RF signals.

FIG. 9B shows an embodiment of a graph 910 to illustrate contact hole critical dimension (CD) growth rates as a function of etch depths. The graph 910 plots a CD growth rate on a y-axis and an etch depth on an x-axis.

In the graph 910, CD growth rates achieved using the square wave signals (FIG. 8) are lower compared to CD growth rates achieved using the RF signals. The CD growth rates for the square wave signals are illustrated in FIG. 9B as circles and the CD growth rates for the RF signals are illustrated in FIG. 9B as circles with crosses (“X”s) in them. The lower CD growth rates are a result of a narrower angular distribution of ions in a high energy ion beam generated by square wave signals.

It should be noted that although the above-embodiments are described with reference to a square wave signal, in some embodiments, the terms triangular wave signal, saw-tooth shaped signal, and square wave signal are used herein interchangeably.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller is part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A system for using a square wave signal for processing a substrate, comprising:
a first pulse generator configured to generate a first square wave signal of a first frequency;
a first filter configured to receive the first square wave signal and filter a second frequency from interfering with the first square wave signal to provide a first filter output signal, wherein the first filter is further configured to provide the first filter output signal via a first radio frequency (RF) transmission line to an electrode disposed within a plasma chamber;
a second pulse generator configured to generate a second square wave signal of a third frequency; and
a second filter configured to receive the second square wave signal and filter the second frequency from interfering with the second square wave signal to provide a second filter output signal, wherein the second filter is further configured to provide the second filter output signal via a second RF transmission line to an edge ring disposed within the plasma chamber.

2. The system of claim 1, further comprising the plasma chamber including the electrode and the edge ring.

3. The system of claim 1, wherein the first filter output signal is a square wave signal and the second filter output signal is a square wave signal.

4. The system of claim 1, wherein the first frequency is equal to the third frequency, and the second frequency is greater than the first and third frequencies.

5. The system of claim 1, further comprising:
a host computer coupled to the first pulse generator, wherein the host computer is configured to:
receive a parameter signal associated with an output of the first filter; and
perform one or more of a plurality of operations including:
a first operation to determine whether a frequency of the parameter signal is within a predetermined frequency range from a predetermined frequency; and
modify the first frequency of the first square wave signal in response to determining that the frequency of the parameter signal is not within the predetermined frequency range from the predetermined frequency, wherein the first frequency of the first square wave signal is modified until the frequency of the parameter signal is within the predetermined frequency range from the predetermined frequency; and
a second operation to determine whether a phase of the parameter signal is within a predetermined phase range from a predetermined phase; and
modify a phase of the first square wave signal in response to determining that the phase of the parameter signal is not within the predetermined phase range from the predetermined phase, wherein the phase of the first square wave signal is modified until the phase of the parameter signal is within the predetermined phase range from the predetermined phase; and
a third operation to determine whether a magnitude of the parameter signal is within a predetermined range from a predetermined magnitude; and
modify a magnitude of the first square wave signal in response to determining that the magnitude of the parameter signal is not within the predetermined range from the predetermined magnitude, wherein the magnitude of the first square wave signal is modified until the magnitude of the parameter signal is within the predetermined range from the predetermined magnitude.

6. The system of claim 1, further comprising:
a host computer coupled to the second pulse generator, wherein the host computer is configured to:
receive a parameter signal associated with an output of the second filter; and
perform one or more of a plurality of operations including:
a first operation to determine whether a frequency of the parameter signal is within a predetermined frequency range from a predetermined frequency; and
modify the third frequency of the second square wave signal in response to determining that the frequency of the parameter signal is not within the predetermined frequency range from the predetermined frequency, wherein the third frequency of the second square wave signal is modified until the frequency of the parameter signal is within the predetermined frequency range from the predetermined frequency; and
a second operation to determine whether a phase of the parameter signal is within a predetermined phase range from a predetermined phase; and
modify a phase of the second square wave signal in response to determining that the phase of the parameter signal is not within the predetermined phase range from the predetermined phase, wherein the phase of the second square wave signal is modified until the phase of the parameter signal is within the predetermined phase range from the predetermined phase; and
a third operation to determine whether a magnitude of the parameter signal is within a predetermined range from a predetermined magnitude; and
modify a magnitude of the second square wave signal in response to determining that the magnitude of the parameter signal is not within the predetermined range from the predetermined magnitude, wherein the magnitude of the second square wave signal is modified until the magnitude of the parameter signal is within the predetermined range from the predetermined magnitude.

7. The system of claim 1, further comprising:
a host computer coupled to the first pulse generator and the second pulse generator, wherein the host computer is configured to:
receive a first parameter signal associated with an output of the first filter;
receive a second parameter signal associated with an output of the second filter;
determine a frequency of the first parameter signal;
determine a frequency of the second parameter signal;
determine whether the frequency of the second parameter signal is within a predetermined frequency range from the frequency of the first parameter signal;
modify the first frequency of the first square wave signal or the third frequency of the second square wave signal upon determining that the frequency of the second parameter signal is not within the predetermined frequency range from the frequency of the first parameter signal, wherein the first frequency or the third frequency is modified until the frequency of the second parameter signal is within the predetermined frequency range from the frequency of the first parameter signal.

8. The system of claim 1, further comprising:
a host computer coupled to the first pulse generator and the second pulse generator, wherein the host computer is configured to:
receive a first parameter signal associated with an output of the first filter;
receive a second parameter signal associated with an output of the second filter;
determine a phase of the first parameter signal;
determine a phase of the second parameter signal;
determine whether the phase of the second parameter signal is within a predetermined phase range from the phase of the first parameter signal;
modify a phase of the first square wave signal or a phase of the second square wave signal upon determining that the phase of the second parameter signal is not within the predetermined phase range from the phase of the first parameter signal, wherein the phase of the first square wave signal or the phase of the second square wave signal is modified until the phase of the second parameter signal is within the predetermined phase range from the phase of the first parameter signal.

9. The system of claim 1, further comprising:
a host computer coupled to the first pulse generator and the second pulse generator, wherein the host computer is configured to:
receive a first parameter signal associated with an output of the first filter;
receive a second parameter signal associated with an output of the second filter;
determine a magnitude of the first parameter signal;
determine a magnitude of the second parameter signal;
determine whether a magnitude of the second parameter signal is within a predetermined magnitude range from the magnitude of the first parameter signal;
change a magnitude of the second square wave signal in response to determining that the magnitude of the second parameter signal is not within the predetermined magnitude range from the magnitude of the first parameter signal, wherein the magnitude of the second square wave signal is changed until the magnitude of the second parameter signal is within the predetermined magnitude range from the magnitude of the first parameter signal.

10. A system for using a square wave signal for processing a substrate, comprising:
a first pulse generator configured to generate a first square wave signal of a first frequency;
a first filter configured to receive the first square wave signal and filter a second frequency from interfering with the first square wave signal to provide a first filter output signal;
a radio frequency (RF) generator configured to generate an RF signal;
an impedance matching circuit configured to receive the RF signal and output a modified signal based on the RF signal;
an RF transmission line coupled to the first filter and the impedance matching circuit to receive the first filter output signal and the modified signal, wherein the RF transmission line is configured to combine the first filter output signal and the modified signal to output a combined signal, wherein the combined signal is configured to be provided to a lower electrode disposed within a plasma chamber.

11. The system of claim 10, further comprising the plasma chamber including the lower electrode.

12. The system of claim 10, wherein the first filter and the impedance matching circuit are situated in same housing.

13. The system of claim 10, wherein the first filter is situated in a first housing and the impedance matching circuit is situated in a second housing.

14. The system of claim 10, further comprising:
a host computer coupled to the first pulse generator and the RF generator, wherein the host computer is configured to:
receive a parameter signal associated with an output of the first filter; and
perform one or more of a plurality of operations including:
a first operation to determine whether a frequency of the parameter signal is within a predetermined frequency range from a predetermined frequency; and
modify the first frequency of the first square wave signal or the second frequency of the RF signal in response to determining that the frequency of the parameter signal is not within the predetermined frequency range from the predetermined frequency, wherein the first frequency of the first square wave signal or the second frequency of the RF signal is modified until the frequency of the parameter signal is within the predetermined frequency range from the predetermined frequency; and
a second operation to determine whether a phase of the parameter signal is within a predetermined phase range from a predetermined phase; and
modify a phase of the first square wave signal or a phase of the RF signal in response to determining that the phase of the parameter signal is not within the predetermined phase range from the predetermined phase, wherein the phase of the first square wave signal or the phase of the RF signal is modified until the phase of the parameter signal is within the predetermined phase range from the predetermined phase; and
a third operation to determine whether a magnitude of the parameter signal is within a predetermined range from a predetermined magnitude; and
modify a magnitude of the first square wave signal or a magnitude of the RF signal in response to determining that the magnitude of the parameter signal is not within the predetermined range from the predetermined magnitude, wherein the magnitude of the first square wave signal or the magnitude of the RF signal is modified until the magnitude of the parameter signal is within the predetermined range from the predetermined magnitude.

15. The system of claim 10, further comprising:
a second pulse generator configured to generate a second square wave signal of a third frequency;
a second filter coupled to the second pulse generator, wherein the second filter is configured to receive the second square wave and filter the second frequency from interfering with the second square wave signal to output a second filter output signal, wherein the second filter output signal is configured to be provided to an edge ring disposed within the plasma chamber.

16. The system of claim 15, wherein the third frequency is equal to the first frequency.

17. The system of claim 15, wherein the first filter output signal is a square wave signal and the second filter output signal is a square wave signal.

18. The system of claim 15, wherein the second pulse generator is configured to be coupled to the edge ring via the second filter without using an impedance matching circuit between the second pulse generator and the edge ring.

19. The system of claim 15, wherein the host computer is configured to:
receive a parameter signal associated with an output of the second filter;
perform one or more of a plurality of operations including:
a first operation to determine whether a frequency of the parameter signal is within a predetermined frequency range from a predetermined frequency; and
modify the third frequency of the second square wave signal in response to determining that the frequency of the parameter signal is not within the predetermined frequency range from the predetermined frequency, wherein the third frequency is modified until the frequency of the parameter signal is within the predetermined frequency range from the predetermined frequency; and
a second operation to determine whether a phase of the parameter signal is within a predetermined phase range from a predetermined phase; and
modify a phase of the second square wave signal in response to determining that the phase of the parameter signal is not within the predetermined phase range from the predetermined phase, wherein the phase of the second square wave signal is modified until the phase of the parameter signal is within the predetermined phase range from the predetermined phase; and
a third operation to determine whether a magnitude of the parameter signal is within a predetermined range from a predetermined magnitude; and
modify a magnitude of the second square wave signal in response to determining that the magnitude of the parameter signal is not within the predetermined range from the predetermined magnitude, wherein the magnitude of the second square wave signal is modified until the magnitude of the parameter signal is within the predetermined range from the predetermined magnitude.

20. The system of claim 15, further comprising:
a host computer coupled to the first pulse generator and the second pulse generator, wherein the host computer is configured to:
receive a first parameter signal associated with an output of the first filter;
receive a second parameter signal associated with an output of the second filter;
determine a frequency of the first parameter signal;
determine a frequency of the second parameter signal;
determine whether the frequency of the second parameter signal is within a predetermined frequency range from the frequency of the first parameter signal;
modify the first frequency of the first square wave signal or the second frequency of the RF signal or the third frequency of the second square wave signal upon determining that the frequency of the second parameter signal is not within the predetermined range from the frequency of the first parameter signal, wherein the first frequency or the second frequency or the third frequency is modified until the frequency of the second parameter signal is within the predetermined range from the frequency of the first parameter signal.

21. The system of claim 15, further comprising:
a host computer coupled to the first pulse generator and the second pulse generator, wherein the host computer is configured to:
receive a first parameter signal associated with an output of the first filter;
receive a second parameter signal associated with an output of the second filter;
determine a phase of the first parameter signal;
determine a phase of the second parameter signal;
determine whether the phase of the second parameter signal is within a predetermined phase range from the phase of the first parameter signal;
modify a phase of the first square wave signal or a phase of the RF signal or a phase of the second square wave signal upon determining that the phase of the second parameter signal is not within the predetermined phase range from the phase of the first parameter signal, wherein the phase of the first square wave signal or the phase of the RF signal or the phase of the second square wave signal is modified until the phase of the second parameter signal is within the predetermined phase range from the phase of the first parameter signal.

22. The system of claim 15, further comprising:
a host computer coupled to the first pulse generator and the second pulse generator, wherein the host computer is configured to:
receive a first parameter signal associated with an output of the first filter;
receive a second parameter signal associated with an output of the second filter;
determine a magnitude of the first parameter signal;
determine a magnitude of the second parameter signal;
determine whether a magnitude of the second parameter signal is within a predetermined magnitude range from the magnitude of the first parameter signal;
change a magnitude of the first square wave signal or a magnitude of the RF signal or a magnitude of the second square wave signal in response to determining that the magnitude of the second parameter signal is not within the predetermined magnitude range from the magnitude of the first parameter signal,
wherein the magnitude of the first square wave signal or the magnitude of the RF signal or the magnitude of the second square wave signal is changed until the magnitude of the second parameter signal is within the predetermined magnitude range from the magnitude of the first parameter signal.

23. The system of claim 10, wherein the first filter is coupled to the first pulse generator via an RF cable, and wherein the first filter is configured to be coupled to the plasma chamber via an RF transmission line without using an impedance matching circuit between the first filter and the plasma chamber.

24. The system of claim 10, wherein the first pulse generator is configured to be coupled to the plasma chamber via the first filter without using an impedance matching circuit between the first pulse generator and the plasma chamber.

25. The system of claim 10, wherein the RF signal has the second frequency that is greater than the first frequency, wherein the RF signal is a sinusoidal signal and the first square wave signal includes a plurality of voltage fluctuations and a main pulse.

26. A method for using a square wave signal for processing a substrate, comprising:
generating a first square wave signal of a first frequency;
filtering a second frequency from interfering with the first square wave signal to provide a first filter output signal;
generating a second square wave signal of a third frequency;
filtering the second frequency from interfering with the second square wave signal to provide a second filter output signal;
providing the first filter output signal to an electrode of a plasma chamber; and
providing the second filter output signal to an edge ring of the plasma chamber.

27. The method of claim 26, wherein the first filter output signal is a square wave signal and the second filter output signal is a square wave signal.
